(19) United States
(12) Patent Application Publication
(10) Pub. No.: US 2025/0221134 A1
(43) Pub. Date: Jul. 3, 2025

(54) DISPLAY DEVICE AND METHOD FOR MANUFACTURING THE SAME

(71) Applicant: Samsung Display Co., LTD., Yongin-si (KR)

(72) Inventors: Ji Wook MOON, Yongin-si (KR); Jong Moo HUH, Yongin-si (KR); Min Woo KIM, Yongin-si (KR); Dong Jun LEE, Yongin-si (KR); Ju Yon LEE, Yongin-si (KR)

(21) Appl. No.: 18/967,380

(22) Filed: Dec. 3, 2024

(30) Foreign Application Priority Data
Dec. 29, 2023 (KR) 10-2023-0197321

(51) Int. Cl. H10H 29/851; H10H 29/85; H10H 29/856

(52) U.S. Cl. CPC H10H 29/8514; H10H 29/8517; H10H 29/856; H10H 29/857

(57) ABSTRACT

A display device and a method for manufacturing the same are provided. A light-emitting element includes semiconductor layers including a first semiconductor layer, an active layer, a second semiconductor layer, and a third semiconductor layer, and defining at least one concave groove that is concave downwardly from one surface of the first semiconductor layer, a first protective layer on side surfaces of the semiconductor layers, on a top surface of the first semiconductor layer, and on inner surfaces of the semiconductor layers and on the third semiconductor layer in the concave groove, and a wavelength conversion layer containing wavelength conversion particles in the concave groove.

### CROSS-REFERENCE TO RELATED APPLICATION

The present application claims priority to, and the benefit of, Korean Patent Application No. 10-2023-0197321, filed on Dec. 29, 2023, in the Korean Intellectual Property Office, the entire disclosure of which is incorporated herein by reference.

### BACKGROUND

### 1. Field

The present disclosure relates to a light-emitting element and a display device.

### 2. Description of the Related Art

The importance of display devices has steadily increased with the development of multimedia technology. Along with this trend, various types of display devices, such as an organic light-emitting display (OLED), a liquid crystal display (LCD) and the like have been used.

A display device is a device for displaying an image, and includes a display panel, such as an organic light-emitting display panel or a liquid crystal display panel. The light-emitting display panel may include light-emitting elements (e.g., light-emitting diodes (LED)). Examples of the light-emitting diode include an organic light-emitting diode (OLED) using an organic material as a light-emitting material, and an inorganic light-emitting diode using an inorganic material as a light-emitting material.

### SUMMARY

Aspects of the present disclosure provide a light-emitting element and a display device capable of securing a wavelength conversion material and a method of increasing a height of a partition wall thereof.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a light-emitting element includes semiconductor layers including a first semiconductor layer, an active layer, a second semiconductor layer, and a third semiconductor layer, and defining at least one concave groove that is concave downwardly from one surface of the first semiconductor layer, a first protective layer on side surfaces of the semiconductor layers, on a top surface of the first semiconductor layer, and on inner surfaces of the semiconductor layers and on the third semiconductor layer in the concave groove, and a wavelength conversion layer containing wavelength conversion particles in the concave groove.

The concave groove may penetrate the first semiconductor layer and the active layer, and may be in at least a part of the second semiconductor layer or the third semiconductor layer.

The light-emitting element may further include a groove reflective layer on the first protective layer in the concave groove.

The light-emitting element may further include an external reflective layer surrounding side surfaces of the first semiconductor layer, the active layer, the second semiconductor layer, and the third semiconductor layer on the first protective layer.

The light-emitting element may further include a second protective layer above the concave groove and covering the external reflective layer.

The concave groove may have a cube shape, a cylindrical shape, or a shape with different respective widths at a top and a bottom thereof.

An area of the concave groove in plan view may be about 50% or less of an area of the light-emitting element in plan view.

The light-emitting element may further include a first contact electrode contacting the first semiconductor layer, and a second contact electrode contacting the second semiconductor layer.

According to one or more embodiments, a display device includes a substrate

on which a pixel electrode layer is disposed, and light-emitting elements above the pixel electrode layer, and including semiconductor layers, a first wavelength conversion layer in a concave groove that is concave in a downward direction from one surface of one of the semiconductor layers, and a first protective layer on side surfaces of the semiconductor layers, on a top surface of a first light-emitting element of the light emitting elements, and on inner surfaces of the semiconductor layers and above one of the semiconductor layers in the concave groove.

The semiconductor layers may include a first semiconductor layer, an active layer, a second semiconductor layer, and a third semiconductor layer, wherein the concave groove penetrates the first semiconductor layer and the active layer, and is in at least a part of the second semiconductor layer or the third semiconductor layer.

The light-emitting elements may further include a groove reflective layer on the first protective layer in the concave groove.

The semiconductor layers may include a first semiconductor layer, an active layer, a second semiconductor layer, and a third semiconductor layer, wherein the light-emitting element further includes an external reflective layer surrounding side surfaces of the first semiconductor layer, the active layer, the second semiconductor layer, and the third semiconductor layer on the first protective layer, and a second protective layer above the concave groove and covering the external reflective layer.

The concave groove may have a cube shape, a cylindrical shape, or a shape with different widths at top and bottom.

The semiconductor layers may include a first semiconductor layer, an active layer, a second semiconductor layer, and a third semiconductor layer, wherein an area of the concave groove in plan view is about 50% or less of an area of the light-emitting element in plan view.

The semiconductor layers may include a first semiconductor layer, an active layer, a second semiconductor layer, and a third semiconductor layer, wherein the first light-emitting element includes a first contact electrode contacting the first semiconductor layer, and a second contact electrode contacting the second semiconductor layer, and wherein the pixel electrode layer includes a pixel electrode connected to the first contact electrode, and a common electrode spaced apart from the pixel electrode and connected to the second contact electrode.

The display device may further include a common electrode on the first light-emitting element, wherein the semiconductor layers include a first semiconductor layer, an active layer, a second semiconductor layer, and a third semiconductor layer, wherein the pixel electrode layer includes a pixel electrode, and wherein the first light-emitting element further includes a contact electrode connecting the first semiconductor layer to the pixel electrode.

The display device may further include a second wavelength conversion layer above the light-emitting elements, wherein the first wavelength conversion layer includes a light transmission pattern or a wavelength conversion pattern, and wherein the second wavelength conversion layer includes another light transmission pattern or another wavelength conversion pattern overlapping the first wavelength conversion layer.

The light-emitting elements may include the first light-emitting element configured to emit light of a first wavelength band, a second light-emitting element configured to emit light of a second wavelength band, and a third light-emitting element configured to emit light of a third wavelength band, wherein the first wavelength conversion layer of the first light-emitting element is configured to convert light of a wavelength other than the first wavelength band into light of the first wavelength band, wherein the first wavelength conversion layer of the second light-emitting element is configured to convert light of a wavelength other than the second wavelength band into light of the second wavelength band, and wherein the first wavelength conversion layer of the third light-emitting element is configured to convert light of a wavelength other than the third wavelength band into light of the third wavelength band.

The light-emitting elements may include the first light-emitting element configured to emit light of a first wavelength band, a second light-emitting element configured to emit light of a second wavelength band, and a third light-emitting element configured to emit light of a third wavelength band, wherein the first wavelength conversion layer of the first light-emitting element is configured to convert light of a wavelength other than the first wavelength band into light of the first wavelength band, wherein the first wavelength conversion layer of the second light-emitting element is configured to convert light of a wavelength other than the second wavelength band into light of the second wavelength band, and wherein the first wavelength conversion layer of the third light-emitting element is configured to convert light of a wavelength other than the third wavelength band into light of the third wavelength band.

The light-emitting elements may be configured to emit first light of a first wavelength band and include the first light-emitting element in a first emission area, a second light-emitting element in a second emission area, and a third light-emitting element in a third emission area, wherein the first wavelength conversion layer of the second light-emitting element includes a first wavelength conversion pattern containing first wavelength conversion particles for converting the first light into second light, wherein the first wavelength conversion layer of the third light-emitting element includes a second wavelength conversion pattern containing second wavelength conversion particles for converting the first light into third light, and wherein the second wavelength conversion layer of the first emission area includes a light transmission pattern containing a base resin and a scatterer for scattering light.

The display device may further include a first color filter in a first emission area and transmitting only a first light of a first wavelength band, a second color filter in a second emission area and transmitting only second light of a second wavelength band, and a third color filter in a third emission area and transmitting only third light of a third wavelength band, wherein the light-emitting elements include the first light-emitting element configured to emit the first light, a second light-emitting element configured to emit the second light, and a third light-emitting element configured to emit the third light, and wherein the first wavelength conversion layer of the light-emitting elements includes a fourth wavelength conversion pattern containing fourth wavelength conversion particles configured to convert the first light into fourth light.

In accordance with a light-emitting element and a display device according to embodiments, light conversion may be effective by filling a groove formed in the light-emitting element with a light conversion material.

However, the aspects of the present disclosure are not limited to the aforementioned aspects, and various other effects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is an equivalent circuit diagram illustrating a sub-pixel according to one or more other embodiments;

FIG. 6 is a layout view illustrating pixels of a display area according to one or more embodiments;

FIG. 7 is a cross-sectional view illustrating an example of a display panel taken along the line B-B′ of FIG. 6;

FIG. 8 is a detailed cross-sectional view showing an example of area A of FIG. 7;

FIG. 9 is a diagram showing an example of the light-emitting element of FIG. 8 according to another modification;

FIGS. 10 and 11 are cross-sectional views showing an example of area A of FIG. 7 in detail according to one or more other embodiments;

FIGS. 12, 13, and 14 are cross-sectional views illustrating an example of a display panel taken along the line B-B′ of FIG. 6 according to one or more other embodiments;

FIG. 15 is a cross-sectional view showing an example of a display panel taken along the line B-B′ of FIG. 6 according to one or more other embodiments;

FIG. 16 is a cross-sectional view showing the configuration of the light-emitting element of FIG. 15;

FIG. 17 is a cross-sectional view showing an example of a display panel taken along the line B-B′ of FIG. 6 according to still one or more other embodiments;

FIG. 18 is a cross-sectional view showing the configuration of the light-emitting element of FIG. 17; and

FIGS. 19 to 30 are cross-sectional views illustrating a method for manufacturing a display device according to one or more embodiments.

FIG. 31 is a diagram schematically showing a virtual reality device including a display device according to one or more embodiments.

FIG. 32 is a diagram schematically showing a smart device including a display device according to one or more embodiments.

FIG. 33 is a diagram schematically showing a vehicle including a display device according to one or more embodiments.

FIG. 34 is a diagram schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof.

Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, specific embodiments will be described with reference to the accompanying drawings.

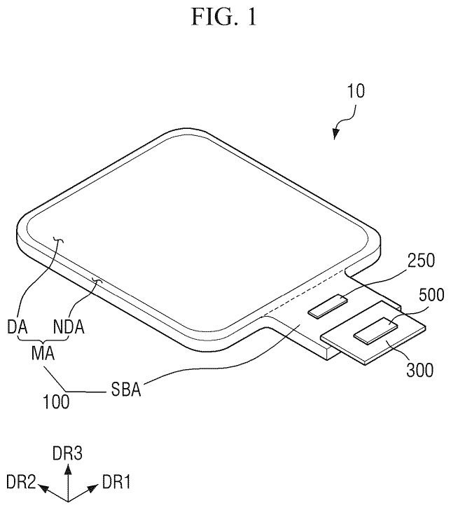

FIG. 1 is a perspective view illustrating a display device according to one or more embodiments.

Referring to FIG. 1, a display device 10 is a device for displaying a moving image or a still image. The display device 10 may be used as a display screen of various devices, such as a television, a laptop computer, a monitor, a billboard, and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light-emitting display device, such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 10 is a micro light-emitting display device, but the present disclosure is not limited thereto. Meanwhile, for simplicity of description, an ultra-small light-emitting diode is referred to hereafter as a micro light-emitting diode.

The display device 10 includes a display panel 100, a display-driving circuit 250, and a circuit board 300.

The display panel 100 may, in plan view, be formed in a rectangular shape having short sides in a first direction DR1, and long sides in a second direction DR2 crossing the first direction DR1. The corner where the short side in the first direction DR1 and the long side in the second direction DR2 meet may be rounded to have a curvature (e.g., predetermined curvature) or may be right-angled. The planar shape of the display panel 100 is not limited to the rectangular shape, and may be formed in another polygonal shape, a circular shape, or an elliptical shape. The display panel 100 may be formed to be flat, but is not limited thereto. For example, the display panel 100 may include a curved portion formed at left and right ends and having a constant curvature or a varying curvature. In addition, the display panel 100 may be formed flexibly so that it can be curved, bent, folded, or rolled.

A substrate SUB of the display panel 100 may include a main region MA and a sub-region SBA.

The main region MA may include a display area DA for displaying an image, and a non-display area NDA that is a peripheral area of the display area DA. The display area DA may include a plurality of pixels displaying an image. For example, the pixel may include a first sub-pixel that emits first light, a second sub-pixel that emits second light, and a third sub-pixel that emits third light.

The sub-region SBA may protrude from one side of the main region MA in the second direction DR2. Although it is shown in FIG. 1 that the sub-region SBA is unfolded, the sub-region SBA may be bent to be arranged on the bottom surface of the display panel 100. In the case where the sub-region SBA is bent, it may overlap the main region MA in a third direction DR3 that is a thickness direction of the display panel 100. The display-driving circuit 250 may be arranged in the sub-region SBA.

The display-driving circuit 250 may generate signals and voltages for driving the display panel 100. The display-driving circuit 250 may be formed as an integrated circuit (IC), and may be attached onto the display panel 100 by a chip-on-glass (COG) method, a chip-on-plastic (COP) method, or an ultrasonic bonding method, but the present disclosure is not limited thereto. For example, the display-driving circuit 250 may be attached onto the circuit board 300 by a chip on film (COF) method.

The circuit board 300 may be attached to one end of the sub-region SBA of the display panel 100. Thus, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible printed circuit board, a printed circuit board, or a flexible film, such as a chip on film.

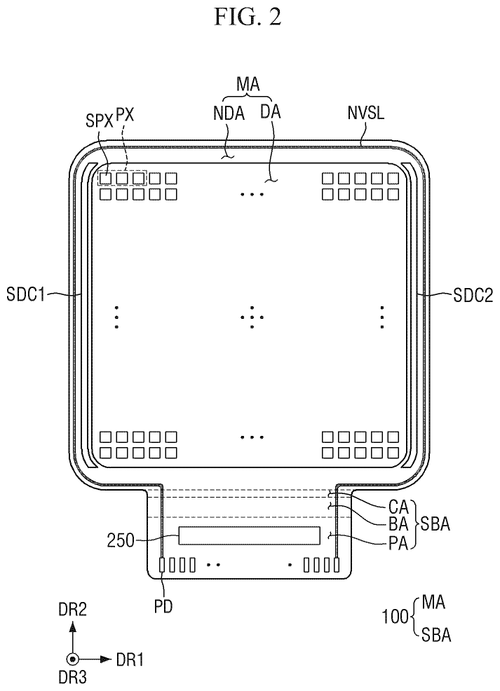

FIG. 2 is a layout view illustrating a display device according to one or more embodiments. It is shown in FIG. 2 that the sub-region SBA is unfolded without being bent.

Referring to FIG. 2, the display panel 100 may include the main region MA and the sub-region SBA.

The main region MA may include the display area DA displaying an image, and the non-display area NDA that is a peripheral area of the display area DA. The display area DA may occupy most of the main region MA. The display area DA may be located at the center of the main region MA.

The display area DA may include a plurality of pixels PX for displaying an image, and each of the plurality of pixels PX may include a plurality of sub-pixels SPX. The pixel PX may be defined as a minimum unit sub-pixel group capable of expressing a white grayscale.

The non-display area NDA may be located adjacent to the display area DA. The non-display area NDA may be an area outside the display area DA. The non-display area NDA may surround the display area DA (e.g., in plan view). The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display-driving circuit 250 through scan fan-out lines. Each of the first scan driver SDC1 and the second scan driver SDC2 may receive scan control signals inputted from the display-driving circuit 250, may generate scan signals in response to the scan control signals, and may output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the display panel 100. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may contact the non-display area NDA of the main region MA, and the other side of the connection area CA may contact the bending area BA.

The pad area PA is an area on which pads PD and the display-driving circuit 250 are located. The display-driving circuit 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may contact the bending area BA.

The bending area BA is an area being bent. When the bending area BA is bent, the pad area PA may be located under the connection area CA and the main region MA. The bending area BA may be located between the connection area CA and the pad area PA. One side of the bending area BA may contact the connection area CA, and the other side of the bending area BA may contact the pad area PA.

A non-display power line NVSL may be located in the non-display area NDA, the connection area CA, the bending area BA, and the pad area PA. The non-display power line NVSL may be located at four sides of the display area DA in the non-display area NDA. The non-display power line NVSL may surround, or may be adjacent to, at least three sides of the display area DA. For example, the non-display power line NVSL may be at the left side, the upper side, and the right side of the display area DA, and may be located in at least a part of the lower side. In addition, the non-display power line NVSL may be located outside the first scan driver SDC1 and outside the second scan driver SDC2. For example, the non-display power line NVSL may be located at the left side of the first scan driver SDC1 and at the right side of the second scan driver SDC2. The non-display power line NVSL may be located at the edges of the first scan driver SDC1 and the substrate SUB, and at the edges of the second scan driver SDC2 and the substrate SUB. Alternatively, the non-display power line NVSL may overlap the first scan driver SDC1 and the second scan driver SDC2.

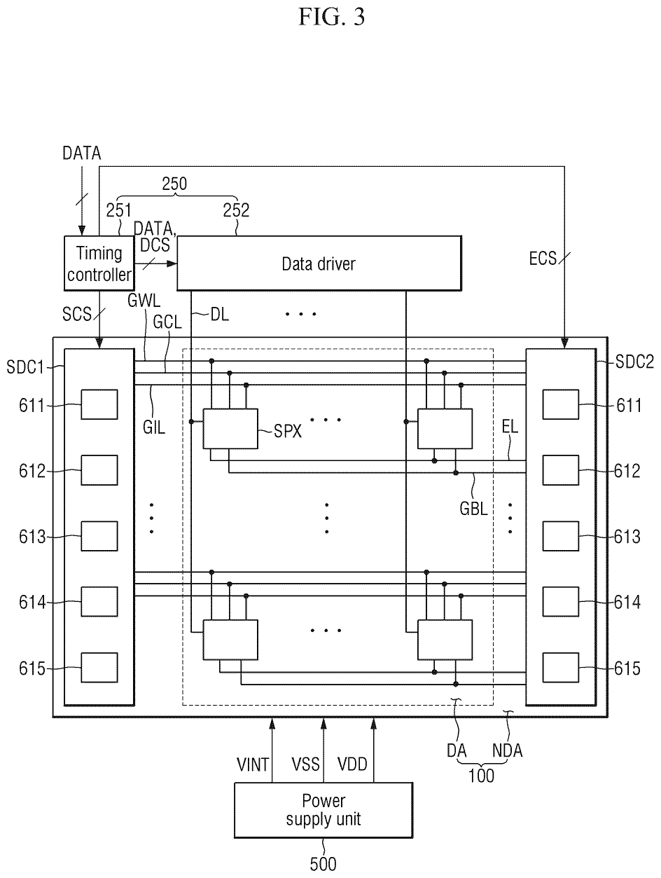

The non-display power line NVSL may be located at the left and right side edges in the connection area CA and bending area BA. The non-display power line NVSL may be connected to the pad PD adjacent to one side edge, and to the pad PD adjacent to the other side edge among the pads PD in the pad area PDA. The non-display power line NVSL may receive a second driving voltage VSS (e.g., see FIG. 3) from the power supply circuit 500 located on the circuit board 300 (as used herein, “located on” may mean “above”).

FIG. 3 is a block diagram illustrating a display device according to one or more embodiments.

Referring to FIG. 3, the display area DA includes the plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1. The plurality of scan lines SL include a plurality of write scan lines GWL, a plurality of control scan lines GCL, a plurality of initialization scan lines GIL, and a plurality of bias scan lines GBL.

Each of the plurality of sub-pixels SPX may be connected to any one write scan line GWL among the plurality of write scan lines GWL, any one control scan line GCL among the plurality of control scan lines GCL, any one initialization scan line GIL among the plurality of initialization scan lines GIL, any one bias scan line GBL among the plurality of bias scan lines GBL, any one emission control line EL among the plurality of emission control lines EL, and any one data line DL among the plurality of data lines DL. Each of the plurality of sub-pixels SPX may receive the data voltage of the data line DL according to the write scan signal of the write scan line GWL, and may emit light from a light-emitting element thereof according to the data voltage.

The non-display area NDA includes the first scan driver SDC1, the second scan driver SDC2, and the display-driving circuit 250.

Each of the first scan driver SDC1 and the second scan driver SDC2 may include a write scan signal output unit 611, a control scan signal output unit 612, an initialization scan signal output unit 613, a bias scan signal output unit 614, and an emission signal output unit 615. Each of the write scan signal output unit 611, the control scan signal output unit 612, the initialization scan signal output unit 613, the bias scan signal output unit 614, and the emission signal output unit 615 may receive a scan-timing control signal SCS from a timing control circuit 251. The write scan signal output unit 611 may generate write scan signals according to the scan-timing control signal SCS of the timing control circuit 400, and may output them sequentially to the write scan lines GWL. The control scan signal output unit 612 may generate control scan signals in response to the scan-timing control signal SCS, and may sequentially output them to the control scan lines GCL. The initialization scan signal output unit 613 may generate initialization scan signals in response to the scan-timing control signal SCS, and may sequentially output them to the initialization scan lines GIL. The bias scan signal output unit 614 may generate bias scan signals according to the scan-timing control signal SCS, and may output them sequentially to bias scan lines GBL. The emission signal output unit 615 may generate emission control signals according to the scan-timing control signal SCS, and may sequentially output them to the emission control lines EL.

The display-driving circuit 250 includes a timing control circuit 251 and a data-driving circuit 252.

The timing control circuit 251 may receive digital video data DATA and timing signals from the outside. The timing control circuit 251 may generate the scan-timing control signal SCS and the data-timing control signal DCS for controlling the display panel 100 in response to the timing signals. The timing control circuit 251 may output the scan-timing control signal SCS to the first scan driver SDC1 and the second scan driver SDC2. The timing control circuit 251 may output the digital video data DATA and the data-timing control signal DCS to the data-driving circuit 252.

The timing control circuit 251 may receive digital video data and timing signals from the outside. The timing control circuit 251 may generate the scan-timing control signal SCS and the data-timing control signal DCS for controlling the display panel 100 in response to the timing signals. The timing control circuit 400 may output the scan-timing control signal SCS to the first scan driver SDC1 and the second scan driver SDC2. The timing control circuit 251 may output the digital video data DATA and the data-timing control signal DCS to the data-driving circuit 252.

The power supply circuit 500 may generate a plurality of panel driving voltages according to a power voltage from the outside. For example, the power supply circuit 500 may generate a first driving voltage VDD, the second driving voltage VSS, and a third driving voltage VINT and supply them to the display panel 100.

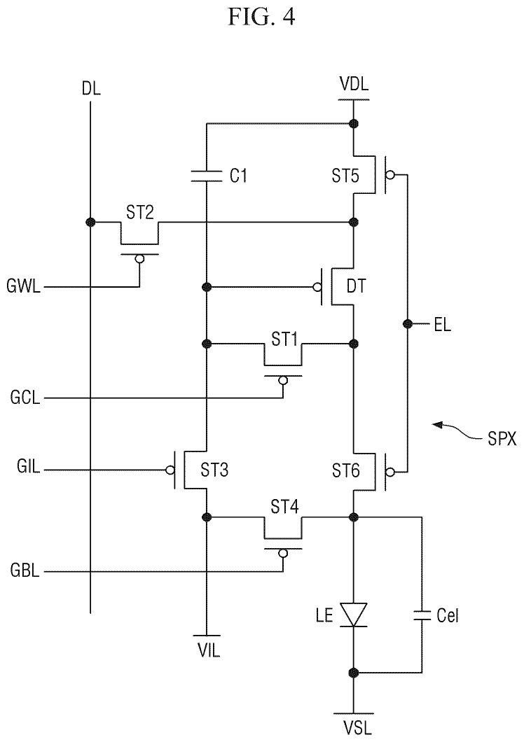

FIG. 4 is an equivalent circuit diagram illustrating a sub-pixel according to one or more embodiments.

Referring to FIG. 4, the sub-pixel SPX according to one or more embodiments may be connected to the scan lines GWL, GIL, GCL, and GBL, the emission control line EL, and the data line DL. For example, the sub-pixel SPX may be connected to the write scan line GWL, the initialization scan line GIL, the control scan line GCL, the bias scan line GBL, the emission control line EL, and the data line DL.

The sub-pixel SPX according to one or more embodiments includes a driving transistor DT, switch elements, a capacitor C1, and a light-emitting element LE. The switch elements include the first to sixth transistors ST1, ST2, ST3, ST4, ST5, and ST6.

The driving transistor DT includes a gate electrode, a first electrode, and a second electrode. The driving transistor DT controls a drain-source current (hereinafter, referred to as “driving current”) flowing between the first electrode and the second electrode according to a data voltage applied to the gate electrode.

The light-emitting element LE may be a micro light-emitting diode element. The light-emitting element LE may emit light according to the driving current. The emission amount of the light-emitting element LE may be proportional to the driving current. The anode electrode of the light-emitting element LE may be connected to the first electrode of the fourth transistor ST4 and the second electrode of the sixth transistor ST6, and the cathode electrode thereof may be connected to a second power line VSL to which a second power voltage is applied.

The capacitor C1 is formed between the gate electrode of the driving transistor DT and a first power line VDL to which a first power voltage is applied. The first power voltage may be the voltage having a level that is higher than that of the second power voltage. One electrode of the capacitor C1 may be connected to the gate electrode of the driving transistor DT, and the other electrode thereof may be connected to the first power line VDL.

As shown in FIG. 4, the first to sixth transistors ST1 to ST6, and the driving transistor DT may all be formed as p-type metal oxide semiconductor field effect transistors (MOSFETs). In this case, the active layer of each of the driving transistor DT and the first to sixth transistors ST1 to ST6 may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1 to ST6 are formed as p-type MOSFETs, they may be turned on when a scan signal and an emission signal of a gate low voltage are applied to the control scan line GCL, the initialization scan line GIL, the write scan line GWL, the bias scan line GBL, and the emission control line EL. One electrode of the third transistor ST3 and one electrode of the fourth transistor ST4 may be connected to the initialization voltage line VIL. The parasitic capacitor Cel may be formed between the anode electrode and cathode electrode of the light-emitting element LE.

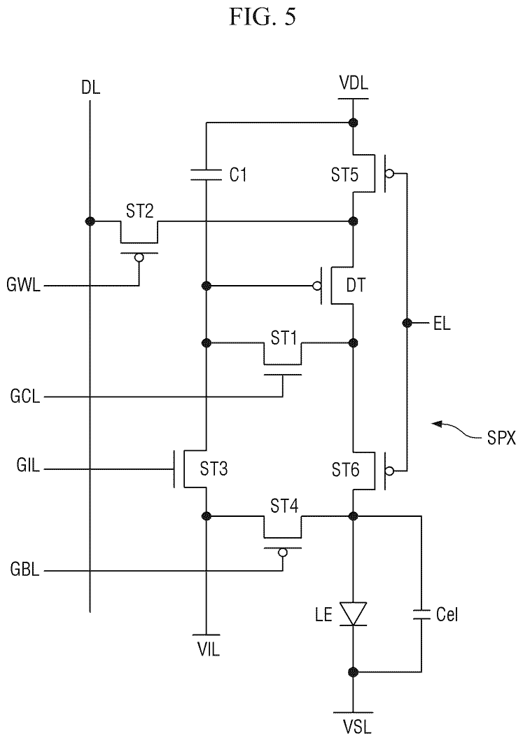

FIG. 5 is an equivalent circuit diagram illustrating a sub-pixel according to one or more other embodiments.

Referring to FIG. 5, the driving transistor DT, the second transistor ST2, the fourth transistor ST4, the fifth transistor ST5, and the sixth transistor ST6 may be configured as p-type MOSFETs, and the first transistor ST1 and the third transistor ST3 may be configured as n-type MOSFETs. An active layer of each of the driving transistor DT, the second transistor ST2, the fourth transistor ST4, the fifth transistor ST5 and the sixth transistor ST6 configured as the P-type MOSFETs may be formed of polysilicon, whereas an active layer of each of the first transistor ST1 and the third transistor ST3 configured as the N-type MOSFETs may be formed of an oxide semiconductor. In this case, the transistors formed of polysilicon and the transistors formed of an oxide semiconductor may be located at different respective layers.

Because the first transistor ST1 and the third transistor ST3 are formed as n-type MOSFETs, the first transistor ST1 may be turned on when the control scan signal of a gate high voltage is applied to the control scan line GCL, and the third transistor ST3 may be turned on when the initialization scan signal is applied to the initialization scan line GIL. In contrast, because the second transistor ST2, the fourth transistor ST4, the fifth transistor ST5, and the sixth transistor ST6 are formed as p-type MOSFETs, they may be turned on when the emission signal and the scan signal of a gate low voltage are applied to each of the write scan line GWL, the bias scan line GBL, and the emission control line EL.

Alternatively, in one or more embodiments, the fourth transistor ST4 may be formed as an n-type MOSFET. In this case, the active layer of the fourth transistor ST4 may also be formed of an oxide semiconductor. When the fourth transistor ST4 is formed as an n-type MOSFET, it may be turned on when the bias scan signal of a gate high voltage is applied to the bias scan line GBL.

Alternatively, in one or more embodiments, the first to sixth transistors ST1 to ST6 and the driving transistor DT may all be formed as n-type MOSFETs. In this case, the active layer of each of the driving transistor DT and the first to sixth transistors ST1 to ST6 may be formed of an oxide semiconductor.

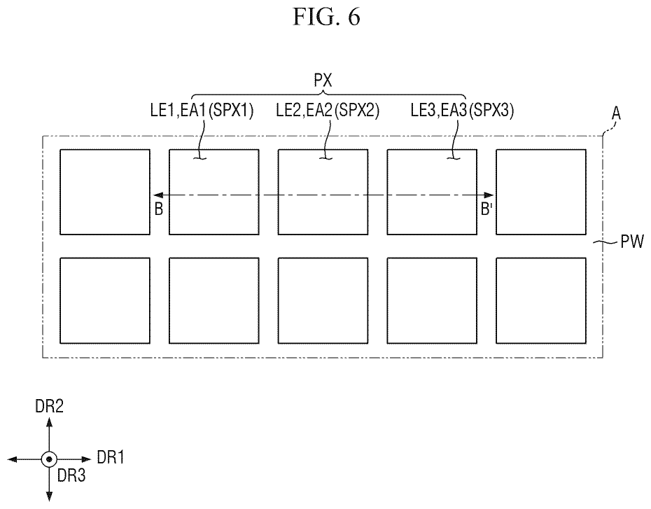

FIG. 6 is a layout view illustrating pixels of a display area according to one or more embodiments.

Referring to FIG. 6, the display area DA may include a plurality of pixels PX. The pixel PX may include a plurality of light-emitting elements LE, and may be defined as a minimum light-emitting unit capable of displaying white light by combining light emitted by the plurality of light-emitting elements LE.

Each of the pixels PX may include a plurality of sub-pixels that emit light, for example, a first sub-pixel SPX1, a second sub-pixel SPX2, and a third sub-pixel SPX3.

The first sub-pixel SPX1, the second sub-pixel SPX2, and the third sub-pixel SPX3 may respectively include a plurality of emission areas EA1, EA2, and EA3 that emit light. Although it is illustrated that each of the plurality of pixels PX includes three emission areas EA1, EA2, and EA3, the present disclosure is not limited thereto. For example, each of the plurality of pixels PX may include four emission areas.

Each of the plurality of emission areas EA1, EA2, and EA3 may include the light-emitting element LE that emits light. The plurality of the emission areas EA1, EA2, and EA3 may respectively include light-emitting elements LE1, LE2, and LE3 that emit light of different respective wavelengths, but the present disclosure is not limited thereto. For example, each of the plurality of emission areas EA1, EA2, and EA3 may include the light-emitting element LE that emits first light. When the plurality of emission areas EA1, EA2, and EA3 include the light-emitting elements LE that emit the same first light, the wavelength of the color of the emission area may be changed by a wavelength conversion layer and/or a color filter. This will be described later.

Although the light-emitting element LE having a quadrilateral planar shape is illustrated, the specification is not limited thereto. For example, the light-emitting element LE may have a polygonal shape other than a quadrilateral shape, a circular shape, an elliptical shape, or an atypical shape.

The first emission areas EA1, the second emission areas EA2, and the third emission areas EA3 may be alternately arranged in the first direction DR1. For example, the first emission areas EA1, the second emission areas EA2, and the third emission areas EA3 may be arranged in the order of the first emission area EA1, the second emission area EA2, and the third emission area EA3 in the first direction DR1.

The first emission areas EA1 may be arranged in the second direction DR2. The second emission areas EA2 may be arranged in the second direction DR2. The third emission areas EA3 may be arranged in the second direction DR2.

The plurality of emission areas EA1, EA2, and EA3 may be partitioned by a partition wall PW. The partition wall PW may surround the light-emitting element LE (e.g., in plan view). The partition wall PW may have a mesh shape, a net shape, or a grid shape in plan view.

FIG. 6 illustrates that each of the emission areas EA1, EA2, and EA3 defined by the partition wall PW has a rectangular shape in plan view, but the present disclosure is not limited thereto. For example, each of the emission areas EA1, EA2, and EA3 defined by the partition wall PW may have a polygonal shape other than the rectangular shape, a circular shape, an elliptical shape, or an atypical shape.

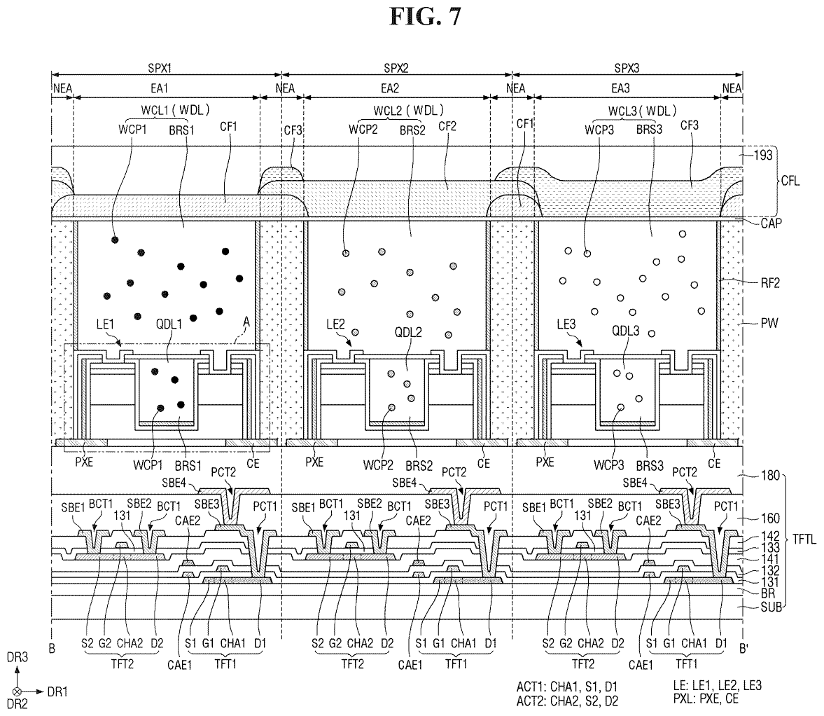

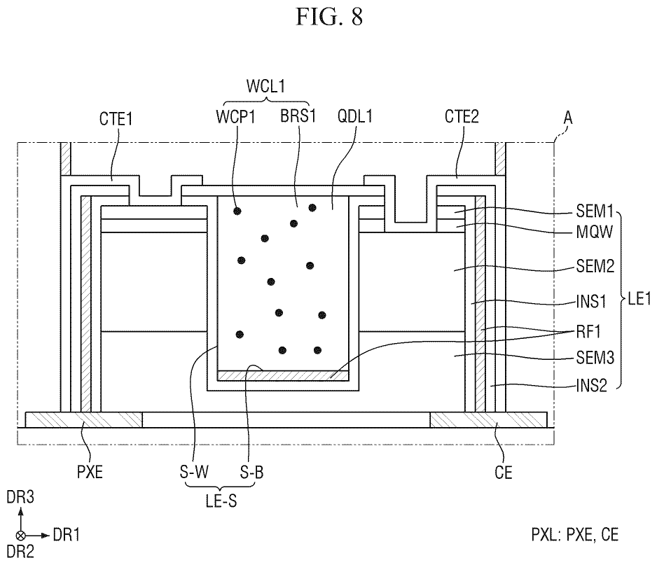

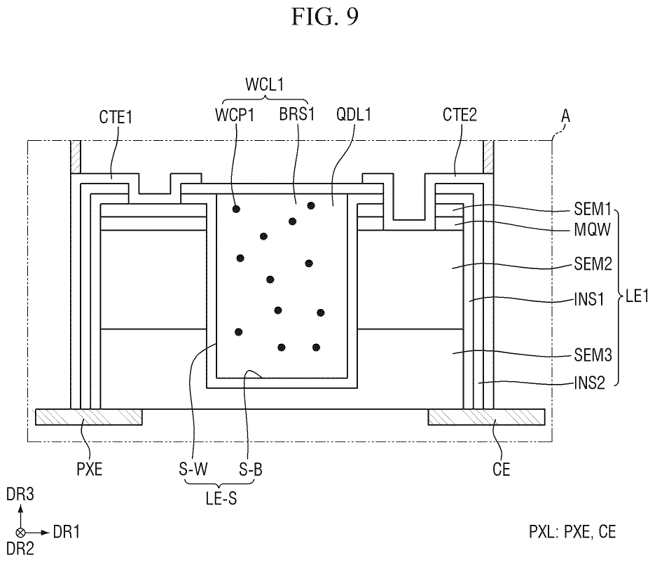

FIG. 7 is a cross-sectional view illustrating an example of a display panel taken along the line B-B′ of FIG. 6. FIG. 8 is a detailed cross-sectional view showing an example of area A of FIG. 7. FIG. 9 is a diagram showing an example of the light-emitting element of FIG. 8 according to another modification.

Referring to FIGS. 7 and 8, the substrate SUB may be made of an insulating material, such as glass or polymer resin. When the substrate SUB is made of polymer resin, it may be a flexible substrate that can be stretched. The polymer resin may include acryl resin, epoxy resin, phenolic resin, polyamide resin, or polyimide resin. The barrier layer BR may be located on the substrate SUB. The barrier layer BR may protect the components located on it from moisture that permeates through the substrate SUB.

The first active layer ACT1 may include a first channel region CHA1, a first source region S1, and a first drain region D1. The first channel region CHA1 may be a region overlapping a first gate electrode G1 in the third direction DR3, which is the thickness direction of the substrate SUB. The first source region S1 may be located at one side of the first channel region CHA1, and the first drain region D1 may be located at the other side of the first channel region CHA1. The first source region S1 and the first drain region D1 may be regions that do not overlap the first gate electrode G1 in the third direction DR3. The first source region S1 and the first drain region D1 may be regions having conductivity by doping a silicon semiconductor with ions.

A first gate-insulating layer 131 may be located on/above a first channel region CHA1, a first source region S1, and a first drain region D1 of a first thin film transistor TFT1. The first gate-insulating layer 131 may be formed of an inorganic layer, for example, a silicon nitride layer, a silicon oxynitride layer, a silicon oxide layer, a titanium oxide layer, or an aluminum oxide layer.

A first gate metal layer may be located on the first gate-insulating layer 131. The first gate metal layer may include a first gate electrode G1 of the first thin film transistor TFT1 and a first capacitor electrode CAE1. The first gate electrode G1 may overlap the first active layer ACT1 in the third direction DR3. FIG. 7 illustrates that the first gate electrode G1 and the first capacitor electrode CAE1 are spaced apart from each other, but the first gate electrode G1 and the first capacitor electrode CAE1 may be connected to each other. The first gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof.

A second gate-insulating layer 132 may be located on the first gate electrode G1 of the first thin film transistor TFT1 and the first capacitor electrode CAE1. The second gate-insulating layer 132 may be formed of an inorganic layer, for example, a silicon nitride layer, a silicon oxynitride layer, a silicon oxide layer, a titanium oxide layer, or an aluminum oxide layer.

A second gate metal layer may be located on the second gate-insulating layer 132. The second gate metal layer may include a second capacitor electrode CAE2. The second capacitor electrode CAE2 may overlap the first capacitor electrode CAE1 in the third direction DR3. Because the second gate-insulating layer 132 has a dielectric constant (e.g., predetermined dielectric constant), the capacitor C1 (see FIG. 5) may be formed by the first capacitor electrode CAE1, the second capacitor electrode CAE2, and the second gate-insulating layer 132 located therebetween. The second gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof.

A first interlayer insulating layer 141 may be located on the second capacitor electrode CAE2. The first interlayer insulating layer 141 may be formed of an inorganic layer, for example, a silicon nitride layer, a silicon oxynitride layer, a silicon oxide layer, a titanium oxide layer, or an aluminum oxide layer.

A second thin film transistor TFT2 may be located on the first interlayer insulating layer 141. The second thin film transistor TFT2 may be any one of the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be located on the first interlayer insulating layer 141. The second active layer ACT2 may include an oxide semiconductor. For example, the second active layer ACT2 may be include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The second active layer ACT2 may include a second channel region CHA2, a second source region S2, and a second drain region D2. The second channel region CHA2 may be a region overlapping the second gate electrode G2 in the third direction DR3. The second source region S2 may be located on one side of the second channel region CHA2, and the second drain region D2 may be located on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

A third gate-insulating layer 133 may be located on the second active layer ACT2 of the second thin film transistor TFT2. The third gate-insulating layer 133 may be formed of an inorganic layer, for example, a silicon nitride layer, a silicon oxynitride layer, a silicon oxide layer, a titanium oxide layer, or an aluminum oxide layer.

A third gate metal layer may be located on the third gate-insulating layer 133. The third gate metal layer may include the second gate electrode G2 of the second thin film transistor TFT2. The second gate electrode G2 may overlap the second active layer ACT2 in the third direction DR3. The third gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof.

A second interlayer insulating layer 142 may be located on the second gate electrode G2 of the second thin film transistor TFT2. The second interlayer insulating layer 142 may be formed of an inorganic layer, for example, a silicon nitride layer, a silicon oxynitride layer, a silicon oxide layer, a titanium oxide layer, or an aluminum oxide layer.

A first data metal layer may be located on the second interlayer insulating layer 142. The first data metal layer may include a first source connection electrode SBE3, a second source connection electrode SBE1, and a third source connection electrode SBE2. The first source connection electrode SBE3 may be connected to the first drain region D1 of the first active layer ACT1 through a first source connection hole PCT1 penetrating the first gate-insulating layer 131, the second gate-insulating layer 132, the first interlayer insulating layer 141, the third gate-insulating layer 133, and the second interlayer insulating layer 142. The second source connection electrode SBE1 may be connected to the second source region S2 of the second active layer ACT2 through a second source connection hole BCT1 penetrating the second interlayer insulating layer 142 and the third gate-insulating layer 133. The third source connection electrode SBE2 may be connected to the second drain region D2 of the second active layer ACT2 through a third source connection hole BCT2 penetrating the second interlayer insulating layer 142 and the third gate-insulating layer 133. The first data metal layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, the first data metal layer may include a first layer made of titanium (Ti), a second layer made of aluminum (Al), and a third layer made of titanium (Ti).

On the first source connection electrode SBE3, the second source connection electrode SBE1, and the third source connection electrode SBE2, a first organic layer 160 for flattening the stepped portion caused by the first thin film transistor TFT1 and the second thin film transistor TFT2 may be located. The first organic layer 160 may be formed of an organic layer, such as acryl resin, epoxy resin, phenolic resin, polyamide resin, polyimide resin, or the like.

The second data metal layer may be located on the first organic layer 160. The second data metal layer may include the fourth source connection electrode SBE4 and a second power line VSL. The fourth source connection electrode SBE4 may be connected to the first source connection electrode SBE3 through a second pixel connection hole PCT2 penetrating the first organic layer 160. The second data metal layer may be formed as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, the second data metal layer may include a first layer made of titanium (Ti), a second layer made of aluminum (Al), and a third layer made of titanium (Ti).

A second organic layer 180 may be located on the fourth source connection electrode SBE4. The second organic layer 180 may be formed of an organic layer, such as acryl resin, epoxy resin, phenolic resin, polyamide resin, polyimide resin, or the like.

The pixel electrode PXE and the common electrode CE may be located on the second organic layer 180. The pixel electrode PXE and the common electrode CE may be located apart from each other.

The pixel electrode layer PXL may include the pixel electrode PXE and the common electrode CE located in each thereof. The pixel electrode PXE may be referred to as an anode electrode, and the common electrode CE may be referred to as a cathode electrode.

The pixel electrode PXE may be connected to the fourth source connection electrode SBE4 through a connection hole penetrating the second organic layer 180. The pixel electrode PXE may be connected to the first source region S1 or the first drain region D1 of the first thin film transistor TFT1 through the first source connection electrode SBE3 and the fourth source connection electrode SBE4. Accordingly, the voltage controlled by the first thin film transistor TFT1 may be applied to the pixel electrode PXE.

The common electrode CE may be connected to neighboring sub-pixels in common. One end of the common electrode CE may be connected to the second power line VSL (see FIG. 4 or FIG. 5). Accordingly, the second driving voltage VSS may be applied to the common electrode CE.

The pixel electrode layer PXL may be formed as a single layer or multiple layers made of any one of molybdenum (Mo), aluminum (Al), silver (Ag), platinum (Pt), palladium (Pd), chromium (Cr), gold (Au), titanium (Ti), nickel (Ni), neodymium (Nd), or copper (Cu) or an alloy thereof. When the pixel electrode layer PXL is made of a metal material with high reflectivity, such as aluminum (Al), among the light emitted from an active layer MQW of the light-emitting element LE, the light traveling in a downward direction with respect to the light-emitting element LE may be reflected from the pixel electrode PXE and the common electrode CE to travel in an upward direction with respect to the light-emitting element LE. Accordingly, because light loss from the light-emitting element LE may be reduced, the light efficiency of the light-emitting element LE may be increased.

The light-emitting element LE may be located on the pixel electrode layer PXL. Although a lateral type micro LED, in which a first contact electrode CTE1 and a second contact electrode CTE2 both protrude from the top surface of the light-emitting element LE and current flows in the lateral direction, is disclosed, the present disclosure is not limited thereto. For example, the first contact electrode CTE1 and the second contact electrode CTE2 may be located at only one surface of the light-emitting element LE.

Each of the plurality of light-emitting elements LE may be made of an inorganic material, such as gallium nitride (GaN). Each of the plurality of light-emitting elements LE may have a length of several to several hundreds of um in each of the first direction DR1, the second direction DR2, and the third direction DR3. For example, each of the plurality of light-emitting elements LE may have a length of about 100 μm or less in each of the first direction DR1, the second direction DR2, and the third direction DR3.

Each of the plurality of light-emitting elements LE may be formed by growing on a semiconductor substrate, such as a silicon substrate or sapphire substrate. The plurality of light-emitting elements LE may be transferred onto the display panel 100 through an electrostatic method using an electrostatic head or a stamping method using an elastic polymer material, such as PDMS or silicone as a transfer substrate.

The plurality of emission areas EA1, EA2, and EA3 may respectively include the light-emitting elements LE1, LE2, and LE3 that emit light of different wavelengths. For example, the first emission area EA1 may include the first light-emitting element LE1 that emits first light, and the first light may be light of a blue wavelength band. The blue wavelength band may be in a range of about 370 nm to about 460 nm, but embodiments of the present specification are not limited thereto.

The second emission area EA2 may include the second light-emitting element LE2 that emits second light, and the second light may be light of a green wavelength band. The green wavelength band may be in a range of about 480 nm to about 560 nm, but embodiments of the present specification are not limited thereto.

The third emission area EA3 may include the third light-emitting element LE3 that emits third light. The third light may be light of a red wavelength band. The red wavelength band may be in a range of about 600 nm to about 750 nm, but embodiments of the present specification are not limited thereto.

Each of the light-emitting elements LE includes a first semiconductor layer SEM1, the active layer MQW, a second semiconductor layer SEM2, an undoped semiconductor layer (also referred to as third semiconductor layer) SEM3, a first wavelength conversion layer QDL1, QDL2, or QDL3, a first protective layer INS1, a first reflective layer RF1, a second protective layer INS2, the first contact electrode CTE1, and the second contact electrode CTE2.

The undoped semiconductor layer SEM3 may be located on the pixel electrode layer PXL. The undoped semiconductor layer SEM3 may be formed as a semiconductor layer that is not doped with an n-type dopant or a p-type dopant, that is, an undoped semiconductor layer. For example, the undoped semiconductor layer SEM3 may be any one of InAlGaN, GaN, AlGaN, InGaN, AlN, or InN, which is not doped with a dopant. For example, the undoped semiconductor layer SEM3 may be GaN that is not doped with a dopant.

The second semiconductor layer SEM2 may be located on the undoped semiconductor layer SEM3. The second semiconductor layer SEM2 may be any one of InAlGaN, GaN, AlGaN, InGaN, AlN, and InN doped with an n-type dopant, such as Si, Ge, Se, or Sn. For example, the second semiconductor layer SEM2 may be n-GaN doped with n-type Si.

The active layer MQW may be located on the second semiconductor layer SEM2. The active layer MQW may emit light by coupling of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately stacked. At this time, the well layer may be formed of InGaN, and the barrier layer may be formed of GaN or AlGaN, but the present disclosure is not limited thereto. Alternatively, the active layer MQW may have a structure in which semiconductor materials having large energy band gap and semiconductor materials having small energy band gap are alternately stacked, and may include other Group III to V semiconductor materials according to the wavelength band of the emitted light.

When the active layer MQW includes InGaN, the color of emitted light may vary depending on the content of indium (In). For example, as the content of indium (In) increases, the wavelength band of the light emitted by the active layer MQW may shift to the red wavelength band, and as the content of indium (In) decreases, the wavelength band of the light emitted by the active layer MQW may shift to the blue wavelength band. For example, the active layer MQW of the light-emitting element LE that emits the third light (light in the blue wavelength band) may contain about 10 wt % to about 20 wt % of indium (In).

The first semiconductor layer SEM1 may be located on the active layer MQW. The first semiconductor layer SEM1 may be any one of InAlGaN, GaN, AlGaN, InGaN, AlN, and InN doped with a p-type dopant, such as Mg, Zn, Ca, or Ba. For example, the first semiconductor layer SEM1 may be p-GaN doped with p-type Mg.

The electron-blocking layer may be located between the first semiconductor layer SEM1 and the active layer MQW. The electron-blocking layer may be a layer for suppressing or preventing too many electrons from flowing into the active layer MQW. For example, the electron-blocking layer may be AlGaN or p-AlGaN doped with p-type Mg. The electron-blocking layer may be omitted.

The superlattice layer may be located between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The superlattice layer may be omitted.

The light-emitting element LE may include a concave groove LE-S that is concave downward from the top surface of the first semiconductor layer SEM1. The light-emitting element LE may include one or more concave grooves LE-S. The concave groove LE-S may penetrate the first semiconductor layer SEM1, the active layer MQW, and the second semiconductor layer SEM2, and may be located in, or defined by, at least a part of the third semiconductor layer SEM3, but the present disclosure is not limited thereto. In another modification, the concave groove LE-S may penetrate the first semiconductor layer SEM1 and the active layer MQW, and may be located in at least a part of the second semiconductor layer SEM2. When viewed from the top of the light-emitting element LE, the area of the concave groove LE-S may be about 50% or less of the area of the light-emitting element LE.

The concave groove LE-S may have a similar shape to the light-emitting

element LE. For example, when the light-emitting element LE is a rectangular parallelepiped or a cube, the concave groove LE-S may also have a rectangular parallelepiped shape or a cube shape. Further, when the light-emitting element LE is cylindrical, the concave groove LE-S may also have a cylindrical shape, but the present disclosure is not limited thereto.

The first protective layer INS1 serves to protect the outer surface of the light-emitting element LE. The first protective layer INS1 may be located on the entire surface of the light-emitting element LE except the bottom of the light-emitting element LE. The first protective layer INS1 may surround the side surface of the concave groove LE-S and the plurality of semiconductor layers SEM1, MQW, SEM2, and SEM3.

For example, the first protective layer INS1 may be located on the top surface of the first semiconductor layer SEM1, the side surfaces of the first semiconductor layer SEM1, the active layer MQW, the second semiconductor layer SEM2, and the third semiconductor layer SEM3, and a bottom surface S-B and a side surface S-W of the concave groove LE-S. Because the side surface S-W is the inner surface of the concave groove LE-S, it may also be referred to as an inner side surface. The first protective layer INS1 may be formed of an inorganic layer, for example, a silicon nitride layer, a silicon oxynitride layer, a silicon oxide layer, a titanium oxide layer, or an aluminum oxide layer.

The first reflective layer RF1 may be located above the bottom surface S-B of the concave groove LE-S and the side surfaces of the first semiconductor layer SEM1, the active layer MQW, the second semiconductor layer SEM2, and the third semiconductor layer SEM3. For simplicity of description, the first reflective layer RF1 located above the bottom surface S-B of the concave groove LE-S may be referred to as a groove reflective layer, and the first reflective layer RF1 located above the side surfaces of the first semiconductor layer SEM1, the active layer MQW, the second semiconductor layer SEM2, and the third semiconductor layer SEM3 may be referred to as an external reflective layer.

The first reflective layer RF1 may contain a metal material having high reflectivity, such as aluminum (Al). The thickness of the first reflective layer RF1 may be about 0.1 μm.

In another modification, as shown in FIG. 9, the first reflective layer RF1 may be omitted.

The first wavelength conversion layer QDL1, QDL2, and QDL3 may be located in a space formed by the concave groove LE-S. The first wavelength conversion layer QDL1, QDL2, and QDL3 may include different wavelength conversion patterns for different emission areas. For example, the first wavelength conversion layer QDL1, QDL2, and QDL3 may include respectively a first wavelength conversion pattern WCL1 in the first emission area EA1, a second wavelength conversion pattern WCL2 in the second emission area EA2, and a third wavelength conversion pattern WCL3 in the third emission area EA3.

The first wavelength conversion pattern WCL1, the second wavelength conversion pattern WCL2, and the third wavelength conversion pattern WCL3 may be located in the concave grooves LE-S formed in the respective light-emitting elements LE. For example, the first wavelength conversion pattern WCL1 may be located in the concave groove LE-S of the first light-emitting element LE1. The second wavelength conversion pattern WCL2 may be located in the concave groove LE-S of the second light-emitting element LE2. The third wavelength conversion pattern WCL3 may be located in the concave groove LE-S of the third light-emitting element LE3.

The first wavelength conversion pattern WCL1 may include a first base resin BRS1 and first wavelength conversion particles WCP1. The first base resin BRS1 may contain a light-transmissive organic material. For example, the first base resin BRS1 may contain epoxy resin, acrylic resin, cardo resin, or imide resin.

The first wavelength conversion particle WCP1 converts light of a different wavelength, which is incident from the first light-emitting element LE1 in the first emission area EA1, into first light. The first wavelength conversion particle WCP1 may be a quantum dot (QD), a quantum rod, a fluorescent material, or a phosphorescent material. Examples of the quantum dot may include Group IV nanocrystal, Group II-VI compound nanocrystal, Group III-V compound nanocrystal, Group IV-VI nanocrystal, and a combination thereof.

The quantum dot (QD) may include a core and a shell that overcoats the core. The core may be at least one of, for example, CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, or Ge, but is not limited thereto. The shell may include at least one of, for example, ZnS, ZnSe, ZnTe, CdS, CdSe, CdTe, HgS, HgSe, HgTe, AlN, AlP, NlAs, AlSb, GaN, GaP, GaAs. GaSb, GaSe, InN, InP, InAs, InSb, TlN, TlP, TlAs, TlSb, PbS, PbSe, or PbTe, but is not limited thereto.

The first wavelength conversion layer QDL1, QDL2, and QDL3 may further include a scatterer for scattering the light of the light-emitting element LE in random directions. In this case, the scatterer may include a metal oxide particle or an organic particle. For example, the metal oxide may be titanium oxide (TiO2), zirconium oxide (ZrO2), silicon dioxide (SiO2), aluminum oxide (Al2O3), indium oxide (In2O3), zinc oxide (ZnOx, which may be ZnO and/or ZnO2), or tin oxide (SnO2). In addition, the organic particles may include an acrylic resin or a urethane-based resin. The diameter of the scatterer may be several to several tens of nanometers.

Through the first wavelength conversion pattern WCL1, the color purity of the first light, which is emitted from the first light-emitting element LE1 and passes through the first wavelength conversion pattern WCL1, is improved.

The second wavelength conversion pattern WCL2 may include a second base resin BRS2 and second wavelength conversion particles WCP2. The second wavelength conversion particle WCP2 converts light of a different wavelength, which is incident from the second light-emitting element LE2 in the second emission area EA2, into second light. The second wavelength conversion particle WCP2 may be a quantum dot (QD), a quantum rod, a fluorescent material, or a phosphorescent material. Through the second wavelength conversion pattern WCL2, the color purity of the second light, which is emitted from the second light-emitting element LE2 and passes through the second wavelength conversion pattern WCL2, is improved.

The third wavelength conversion pattern WCL3 may include a third base resin BRS3 and third wavelength conversion particles WCP3. The third wavelength conversion particle WCP3 converts light of a different wavelength, which is incident from the third light-emitting element LE3 in the third emission area EA3, into third light. The third wavelength conversion particle WCP3 may be a quantum dot (QD), a quantum rod, a fluorescent material, or a phosphorescent material. Through the third wavelength conversion pattern WCL3, the color purity of the third light, which is emitted from the third light-emitting element LE3 and passes through the third wavelength conversion pattern WCL3, is improved. When each wavelength conversion particle is made of a fluorescent material or a phosphorescent material, the second protective layer INS2 may be omitted, because the fluorescent or phosphorescent material is resistant to moisture.

The second protective layer INS2 may be located on one surface of the light-emitting element LE where the concave groove LE-S is provided, and on the side surface of the light-emitting element LE.

The second protective layer INS2 may serve to seal the top surface of the first wavelength conversion layer QDL1, QDL2, and QDL3. The second protective layer INS2 may be located on the first reflective layer RF1 located at the side surface of the light-emitting element LE. For example, the second protective layer INS2 may be located above the top surface of the first semiconductor layer SEM1 and the side surface of each of the first semiconductor layer SEM1, the active layer MQW, the second semiconductor layer SEM2, and the undoped semiconductor layer SEM3 of the light-emitting element LE. The second protective layer INS2 may be made of the same material as the first protective layer INS1. For example, the second protective layer INS2 may be formed of an inorganic layer, for example, a silicon nitride layer, a silicon oxynitride layer, a silicon oxide layer, a titanium oxide layer, or an aluminum oxide layer.

The first contact electrode CTE1 and the second contact electrode CTE2 may be located at the top surface of the light-emitting element LE. The first contact electrode CTE1 may extend from the top surface of the light-emitting element LE to be located at one side surface thereof. The second contact electrode CTE2 may extend from the top surface of the light-emitting element LE to be located at one side surface thereof.

The first contact electrode CTE1 may contact the first semiconductor layer SEM1 at the top surface of the light-emitting element LE. To this end, the top surface of the light-emitting element LE may include a first hole exposing the first semiconductor layer SEM1. The first contact electrode CTE1 may be electrically connected to the first semiconductor layer SEM1 exposed by the first hole.

The first contact electrode CTE1 may be electrically connected to the pixel electrode PXE. The first contact electrode CTE1 may directly contact the pixel electrode PXE, but the present disclosure is not limited thereto. The first contact electrode CTE1 may be connected to the pixel electrode PXE via a separate connection electrode.

The second contact electrode CTE2 may contact the second semiconductor layer SEM2 at the top surface of the light-emitting element LE. To this end, the top surface of the light-emitting element LE may include a second hole exposing the second semiconductor layer SEM2. The second contact electrode CTE2 may be electrically connected to the second semiconductor layer SEM2 exposed by the second hole.

The second contact electrode CTE2 may be electrically connected to the common electrode CE. The second contact electrode CTE2 may directly contact the common electrode CE, but the present disclosure is not limited thereto. The second contact electrode CTE2 may be connected to the common electrode CE via a separate connection electrode.

Because the first contact electrode CTE1 and the second contact electrode CTE2 are located at the top surface of the light-emitting element LE, they may be transparent electrodes. For example, the first contact electrode CTE1 and the second contact electrode CTE2 may be made of a transparent conductive oxide, such as indium tin oxide (ITO) or indium zinc oxide (IZO).

The partition wall PW is located between the plurality of light-emitting elements LE and between the second wavelength conversion layers WDL. The partition wall PW may partition the plurality of emission areas EA1, EA2, and EA3 and a non-emission area NEA. The partition wall PW may be formed in a grid-like pattern throughout the display area DA. Further, the partition wall PW may not overlap the plurality of emission areas EA1, EA2, and EA3, and may overlap the non-emission area NEA.

The partition wall PW may serve to provide a space for forming the second wavelength conversion layer WDL. That is, the partition wall PW may define the area of the second wavelength conversion layer WDL. The partition wall PW may contain an organic insulating material to have a thickness (e.g., predetermined thickness). The organic insulating material may contain, for example, epoxy resin, acrylic resin, cardo resin or imide resin. In one or more embodiments, the partition wall PW is illustrated as being made of a single layer between the plurality of light-emitting elements LE and between the second wavelength conversion layers WDL, but the present disclosure is not limited thereto. For example, the partition wall PW may include a first partition wall located between the plurality of light-emitting elements LE and a second partition wall located between the second wavelength conversion layers WDL.

A second reflective layer RF2 is located on a side surface of a space for the second wavelength conversion layer WDL formed in the partition wall PW, which will be described later. The second reflective layer RF2 may be located on the side surface of each of the partition wall PW and the second wavelength conversion layer WDL. That is, one surface of the second reflective layer RF2 may contact the side surface of the second wavelength conversion layer WDL, and the other surface thereof may contact the partition wall PW. The second reflective layer RF2 may overlap the emission area. The second reflective layer RF2 may contain a metal material having high reflectivity, such as aluminum (Al). The thickness of the second reflective layer RF2 may be about 0.1 μm. The first reflective layer RF1 and the second reflective layer RF2 may be formed of the same material, but are not limited thereto. Alternatively, the second reflective layer RF2 may include M (M being an integer of 2 or more) pairs of first layers and second layers having different refractive indices to serve as a distributed Bragg reflector (DBR). In this case, M first layers and M second layers may be located alternately. The first layer and the second layer may be formed of an inorganic layer, for example, a silicon nitride layer, a silicon oxynitride layer, a silicon oxide layer, a titanium oxide layer, or an aluminum oxide layer.

The second reflective layer RF2 may reduce or prevent light color mixture among the emission areas EA1, EA2, and EA3.

The second wavelength conversion layer WDL includes a different wavelength conversion pattern with respect to a different emission area, but includes the same wavelength conversion pattern as that of the first wavelength conversion layer QDL1, QDL2, and QDL3 located in the same emission area. For example, the second wavelength conversion layer WDL may include a first wavelength conversion pattern WCL1 in the first emission area EA1, a second wavelength conversion pattern WCL2 in the second emission area EA2, a third wavelength conversion pattern WCL3 in the third emission area EA3.

A capping layer CAP may be located on the partition wall PW and the second wavelength conversion layer WDL. The capping layer CAP may serve to protect the wavelength conversion particles WCP1, WCP2, and WCP3 of the second wavelength conversion layer WDL from moisture permeation.

A color filter layer CFL may be located on the capping layer CAP. The color filter layer CFL may include a first color filter CF1, a second color filter CF2, a third color filter CF3, and an overcoat layer 193.

The first color filter CF1 may be located on the second wavelength conversion layer WDL in the first emission area EA1. The first color filter CF1 may transmit the first light, and may block or absorb light of a different wavelength. For example, the first color filter CF1 may transmit light in the blue wavelength band, and may absorb or block light in the green and red wavelength bands. Accordingly, the first emission area EA1 of the first sub-pixel SPX1 may emit first light (light in the blue wavelength band).

The second color filter CF2 may be located on the second wavelength conversion layer WDL in the second emission area EA2. The second color filter CF2 may transmit the second light, and may block or absorb light of a different wavelength. For example, the second color filter CF2 may transmit light in the green wavelength band, and may absorb or block light in the blue and red wavelength bands. Accordingly, the second emission area EA2 of the second sub-pixel SPX2 may emit second light (light in the green wavelength band).

The third color filter CF3 may be located on the second wavelength conversion layer WDL in the third emission area EA3. The third color filter CF3 located in the third emission area EA3 may transmit third light (light in the red wavelength band), and may absorb or block light in other wavelengths. For example, the third color filter CF3 may transmit light in the red wavelength band, and may absorb or block light in the green and blue wavelength bands. Accordingly, the third emission area EA3 of the third sub-pixel SPX3 may emit the third light (light in the red wavelength band).

The area in which the first color filter CF1, the second color filter CF2, and the third color filter CF3 overlap may serve to block light. The area in which the first color filter CF1, the second color filter CF2, and the third color filter CF3 overlap may overlap the partition wall PW.

The overcoat layer 193 may be located on the plurality of color filters CF1, CF2, and CF3. The overcoat layer 193 may be located directly on the color filter layer CFL. The overcoat layer 193 may be entirely located in the display area DA, and may have a flat surface. The overcoat layer 193 may flatten the stepped portion formed by the color filter layer CFL located thereunder. The overcoat layer 193 may include a light-transmitting organic material.

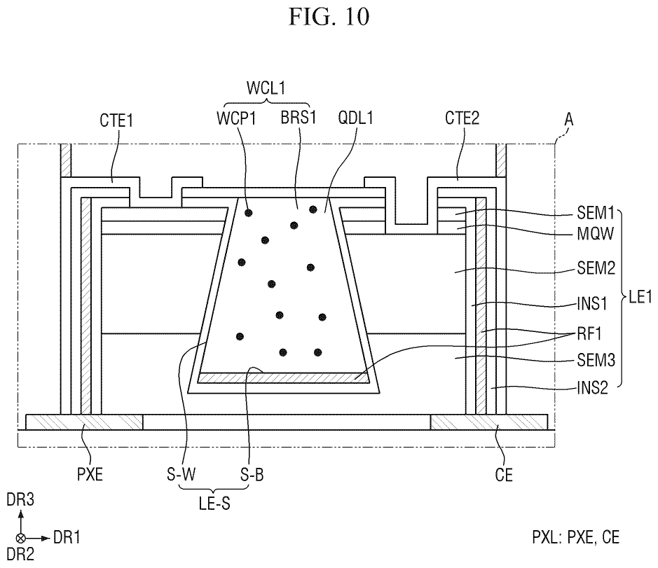

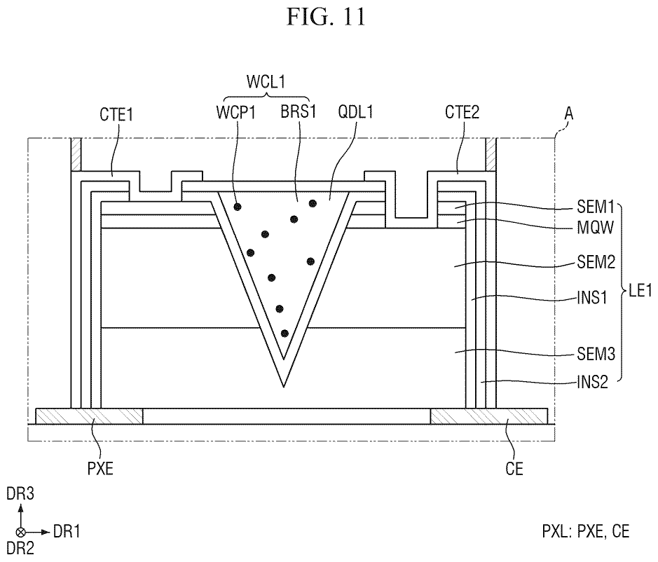

Hereinafter, a light-emitting element according to one or more other embodiments will be described with reference to FIGS. 10 and 11.

FIGS. 10 and 11 are cross-sectional views showing an example of area A of FIG. 7 in detail according to one or more other embodiments.

Referring to FIGS. 10 and 11, the first light-emitting element LE1 is different from the first light-emitting element LE1 of FIGS. 8 and 9 in that the concave groove LE-S of the first light-emitting element LE1 is formed to have different upper and lower widths. Redundant description of parts already described in the one or more embodiments corresponding to FIGS. 8 and 9 will be omitted.

Referring to FIG. 10, the first light-emitting element LE1 is different from the first light-emitting element LE1 of FIG. 8 in that the concave groove LE-S of the first light-emitting element LE1 is formed in a structure in which the width increases in a downward direction.

The first wavelength conversion layer QDL1 is formed in a structure in which the width increases as going downward. The width of the first wavelength conversion layer QDL1 may gradually increase in the first semiconductor layer SEM1, the active layer MQW, the second semiconductor layer SEM2, and the third semiconductor layer SEM3. Compared to the active layer MQW in the one or more embodiments corresponding to FIG. 8, the active layer MQW in the one or more embodiments corresponding to FIG. 10 may secure a relatively larger area.

Meanwhile, referring to FIG. 11, the first wavelength conversion layer QDL1 is formed in a structure in which the width decreases in a downward direction. The width of the first wavelength conversion layer QDL1 may gradually decrease in the first semiconductor layer SEM1, the active layer MQW, the second semiconductor layer SEM2, and the third semiconductor layer SEM3. The structure, in which the first wavelength conversion layer QDL1 becomes narrower as going downward, may be advantageous in terms of process. In the structure that becomes narrower as going downward, the first reflective layer RF1 may be omitted.

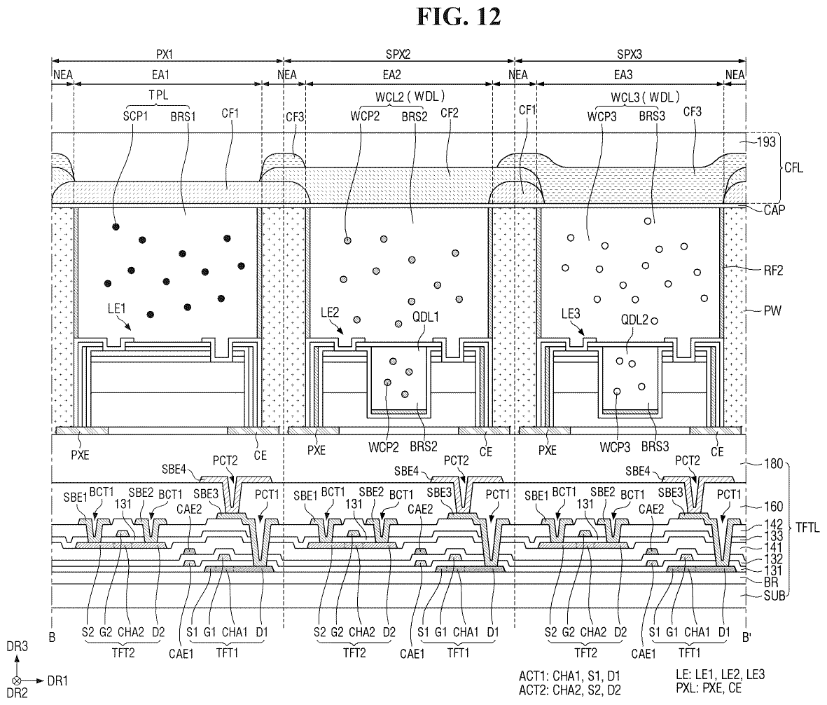

FIGS. 12 to 14 are cross-sectional views illustrating an example of a display panel taken along the line B-B′ of FIG. 6 according to one or more other embodiments.

Referring to FIG. 12, the display panel shown is different from the display panel described with reference to FIGS. 7 and 8 in that the light-emitting elements LE located in different sub-pixels emit the same first light, for example, blue light. It is different from the light-emitting element LE of FIGS. 7 and 8. Redundant description of parts already described in the one or more embodiments corresponding to FIGS. 7 and 8 will be omitted.

Referring to FIG. 12, each of the plurality of emission areas EA1, EA2, and EA3 may include the light-emitting element LE that emits first light. The first light may be light of a blue wavelength band. The blue wavelength band may be in a range of about 370 nm to about 460 nm, but embodiments of the present specification are not limited thereto.

The first emission area EA1 may include the first light-emitting element LE1, a light transmission pattern TPL, and the first color filter CF1. The first light-emitting element LE1, the light transmission pattern TPL, and the first color filter CF1 may overlap in the third direction DR3. The first light-emitting element LE1 may be different from the first light-emitting element LE1 described with reference to FIG. 7 in that it does not include the first wavelength conversion layer. The light transmission pattern TPL may transmit the first light outputted from the first light-emitting element LE1 without conversion, and the first color filter CF1 may transmit the first light. Accordingly, each of the first emission areas EA1 may emit the first light.

The light transmission pattern TPL may transmit incident light. The light transmission pattern TPL may transmit the first light, which is blue light emitted from the first light-emitting element LE1 located in the first emission area EA1, without conversion. The light transmission pattern TPL may include a first base resin BRS1, and a scatterer SCP dispersed in the first base resin BRS1.

In one or more embodiments, the first wavelength conversion pattern may be located instead of the light transmission pattern TPL. The first wavelength conversion pattern may include a blue phosphor.

Each of the second emission areas EA2 may include the second light-emitting element LE2, the second wavelength conversion layer WDL, and the second color filter CF2. The second light-emitting element LE2, the second wavelength conversion layer WDL, and the second color filter CF2 may overlap in the third direction DR3. The second light-emitting element LE2 may include the first wavelength conversion layer QDL1. The first wavelength conversion layer QDL1 of the second light-emitting element LE2 may include the second wavelength conversion pattern WCL2. Accordingly, the second wavelength conversion pattern WCL2 converts a part of the first light outputted from the second light-emitting element LE2 into second light. For example, the second light may be light of the green wavelength band. The second wavelength conversion layer WDL converts the first light that was not converted by the first wavelength conversion layer QDL1 into second light. The second color filter CF2 may transmit the second light. Accordingly, each of the second emission areas EA2 may emit the second light.

Each of the third emission areas EA3 may include the third light-emitting element LE3, the second wavelength conversion layer WDL, and the third color filter CF3. The third light-emitting element LE3, the second wavelength conversion layer WDL, and the third color filter CF3 may overlap in the third direction DR3. The third light-emitting element LE3 may include the first wavelength conversion layer QDL2. The first wavelength conversion layer QDL2 of the third light-emitting element LE3 may include the third wavelength conversion pattern WCL3. Accordingly, the third wavelength conversion pattern WCL3 converts a part of the first light outputted from the third light-emitting element LE3 into third light. For example, the third light may be light of the red wavelength band. The second wavelength conversion layer WDL converts the first light, which was not converted by the first wavelength conversion layer QDL2, into third light. The third color filter CF3 may transmit the third light. Accordingly, each of the third emission areas EA3 may emit the third light.

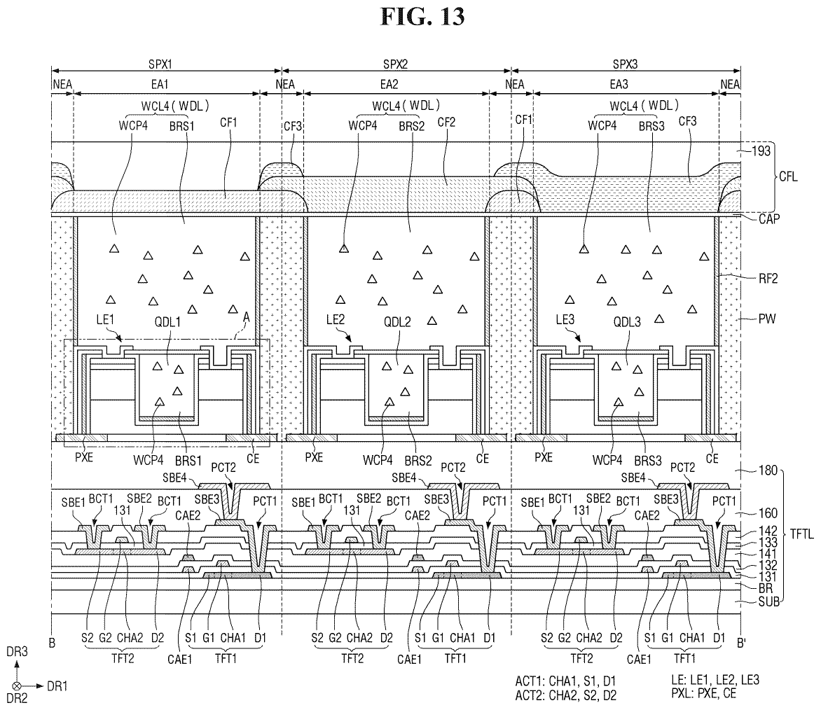

Referring to FIG. 13, the display panel shown is different from the display panel described with reference to FIGS. 7 and 8 in that the first wavelength conversion layer QDL1, QDL2, and QDL3 and the second wavelength conversion layer WDL located in different sub-pixels have the same wavelength conversion particles. It is different from the light-emitting element LE of FIGS. 7 and 8. Redundant description of parts already described in the one or more embodiments corresponding to FIGS. 7 and 8 will be omitted.

Referring to FIG. 13, the first emission area EA1 may include the first light-emitting element LE1, the second wavelength conversion layer WDL, and the first color filter CF1. The first light-emitting element LE1 emits the first light, and the first light-emitting element LE1 has the first wavelength conversion layer QDL1. The first light is light of blue wavelength band.

The first wavelength conversion layer QDL1 and the second wavelength conversion layer WDL may include a fourth wavelength conversion pattern WCL4. The fourth wavelength conversion pattern WCL4 may include a first base resin BRS1 and fourth wavelength conversion particles WCP4. The fourth wavelength conversion particle WCP4 converts light outputted from the light-emitting element LE into fourth light. For example, the fourth wavelength conversion pattern WCL4 may convert the first light outputted from the first light-emitting element LE1 into fourth light. The fourth wavelength conversion particle WCP4 may be a quantum dot (QD), a quantum rod, a fluorescent material, or a phosphorescent material.

Accordingly, the first color filter CF1 of the first emission area EA1 may transmit only the first light from white light that is fifth light, the second color filter CF2 of the second emission area EA2 may transmit only the second light from the white light that is the fifth light, and the third color filter CF3 of the third emission area EA3 may transmit only the third light from the white light that is the fifth light.

In another modification, even when the first light-emitting element LE1, the second light-emitting element LE2, and the third light-emitting element LE3 emit the first light, for example, light of a blue wavelength band, the first wavelength conversion layer QDL1, QDL2, and QDL3 and the second wavelength conversion layer WDL may have the fourth wavelength conversion pattern WCL4. For example, the first light, which is outputted from the light-emitting elements LE of the first emission area EA1, the second emission area EA2, and the third emission area EA3, may be converted into fourth light and emitted. For example, the fourth light may be light of a yellow wavelength band. The fourth light may be light of both a green wavelength band and a red wavelength band. That is, the fourth light may be a mixture of the second light and the third light. The first color filter CF1 of the first emission area EA1 transmits the first light, the second color filter CF2 of the second emission area EA2 transmits the second light, and the third color filter CF3 of the third emission area EA3 transmits the third light.

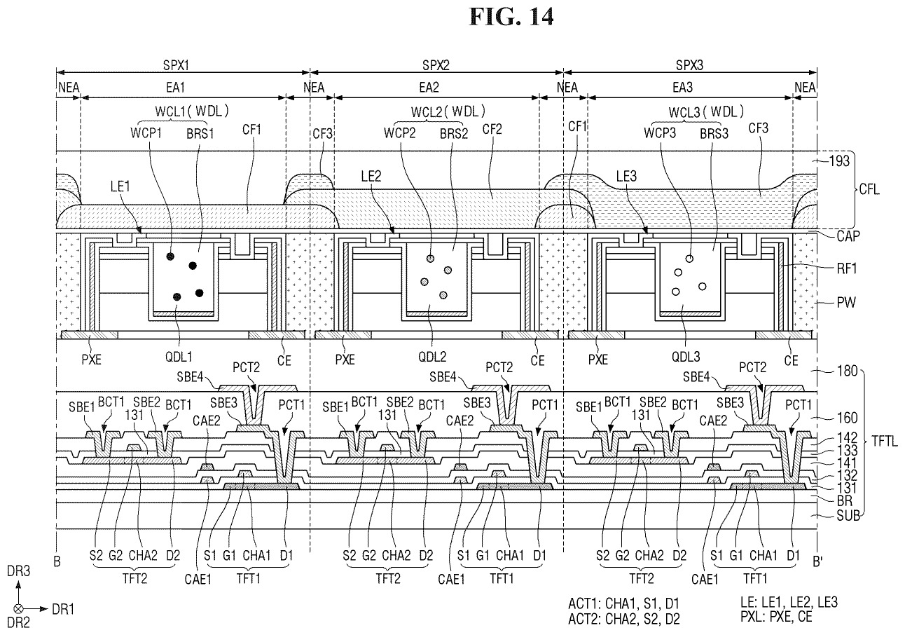

Referring to FIG. 14, the display panel shown is different from the display panel described with reference to FIGS. 7 and 8 in that the second wavelength conversion layers located in different sub-pixels are omitted. It is different from the light-emitting element LE of FIGS. 7 and 8. Redundant description of parts already described in the one or more embodiments corresponding to FIGS. 7 and 8 will be omitted.

The color filter layer CFL may be located on the partition wall PW and the light-emitting element LE in each of the emission areas EA1, EA2, and EA3. For example, the first color filter CF1 may be located on the first light-emitting element LE1 of the first emission area EA1 without the second wavelength conversion layer. The second color filter CF2 may be located on the second light-emitting element LE2 in the second emission area EA2 without the second wavelength conversion layer. The third color filter CF3 may be located on the third light-emitting element LE3 in the third emission area EA3 without the second wavelength conversion layer. The one or more embodiments corresponding to FIG. 14 has an advantage that the thickness of the display panel may be reduced.

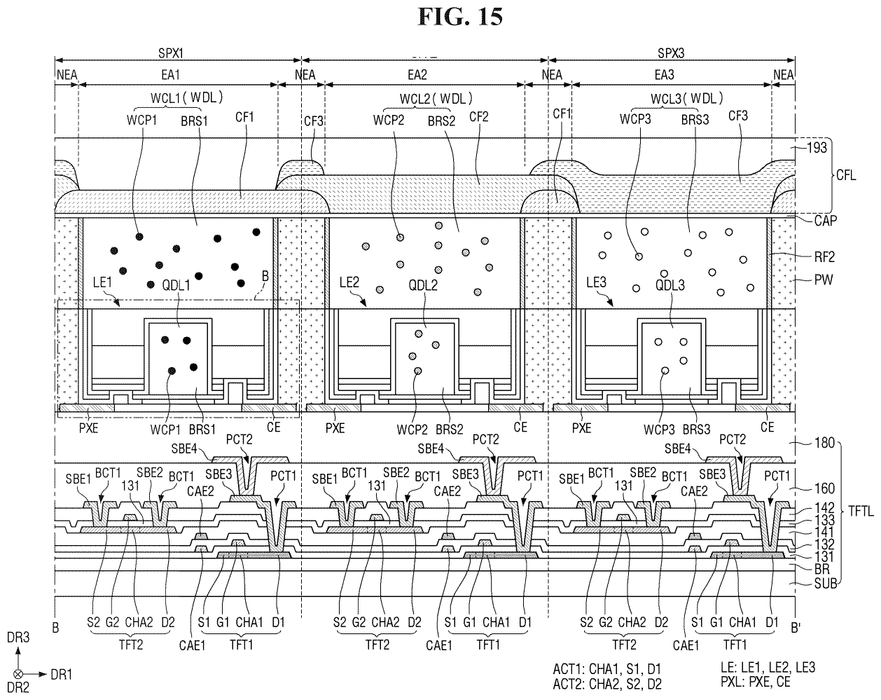

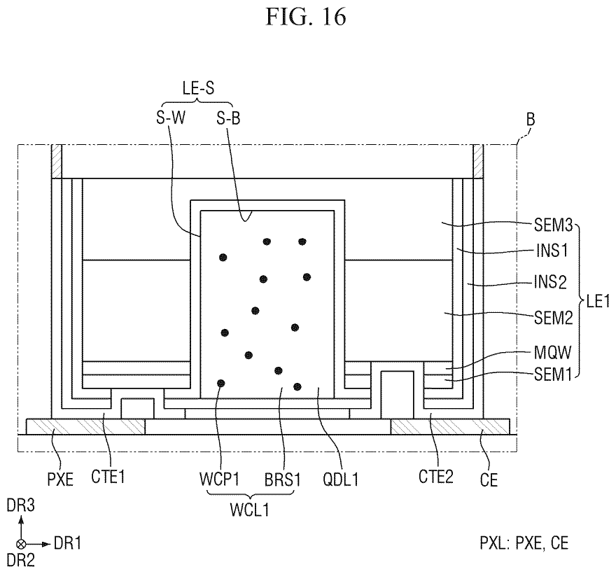

FIG. 15 is a cross-sectional view showing an example of a display panel taken along the line B-B′ of FIG. 6 according to one or more other embodiments. FIG. 16 is a cross-sectional view showing the configuration of the light-emitting element of FIG. 15. FIG. 16 is a detailed cross-sectional view showing an example of area B of FIG. 15.

Referring to FIGS. 15 and 16, the display panel shown is different from the display panel described with reference to FIGS. 7 and 8 in that the light-emitting elements LE have the first contact electrode CTE1 and the second contact electrode CTE2 facing the pixel electrode layer PXL, and not extending to the side surface of the light-emitting element LE. Redundant description of parts already described in the one or more embodiments corresponding to FIGS. 7 and 8 will be omitted.

Referring to FIG. 15, the substrate SUB may be a semiconductor substrate, for example, a silicon substrate. For example, the substrate SUB may be a CMOS substrate, but is not limited thereto. For example, the substrate SUB may be formed of an insulating material, such as glass or a polymer resin. When the substrate SUB is made of polymer resin, it may be a flexible substrate that can be stretched. The polymer resin may include acryl resin, epoxy resin, phenolic resin, polyamide resin, or polyimide resin.

Each of the plurality of light-emitting elements LE includes the first semiconductor layer SEM1, the active layer MQW, the second semiconductor layer SEM2, the undoped semiconductor layer SEM3, the first wavelength conversion layer QDL1, the first protective layer INS1, the second protective layer INS2, the first contact electrode CTE1, and the second contact electrode CTE2.

The first semiconductor layer SEM1, the active layer MQW, the second semiconductor layer SEM2, and the undoped semiconductor layer SEM3 may be stacked in that order. A current spreading layer and the like may be additionally located on the first semiconductor layer SEM1. The current spreading layer may be a layer to increase light extraction efficiency and may be formed of a transparent conductive oxide (TCO), such as indium tin oxide (ITO) or indium zinc oxide (IZO) that can transmit light.

The first contact electrode CTE1 may be located on an opening exposing the first semiconductor layer SEM1 to contact the first semiconductor layer SEM1. The second contact electrode CTE2 may be located on an opening exposing the second semiconductor layer SEM2 to contact the second semiconductor layer SEM2.

The first contact electrode CTE1 may be located on the pixel electrode PXE, and the second contact electrode CTE2 may be located on the common electrode CE. The first contact electrode CTE1 may be electrically connected to the pixel electrode PXE. The first contact electrode CTE1 may be connected directly to the pixel electrode PXE, or may be connected thereto via a connection electrode. The second contact electrode CTE2 may be electrically connected to the common electrode CE. The second contact electrode CTE2 may be connected directly to the common electrode CE, or may be connected thereto via a connection electrode.

The first contact electrode CTE1 and the second contact electrode CTE2 may include any one of molybdenum (Mo), aluminum (Al), chromium (Cr), gold (Au), titanium (Ti), nickel (Ni), neodymium (Nd), or copper (Cu).

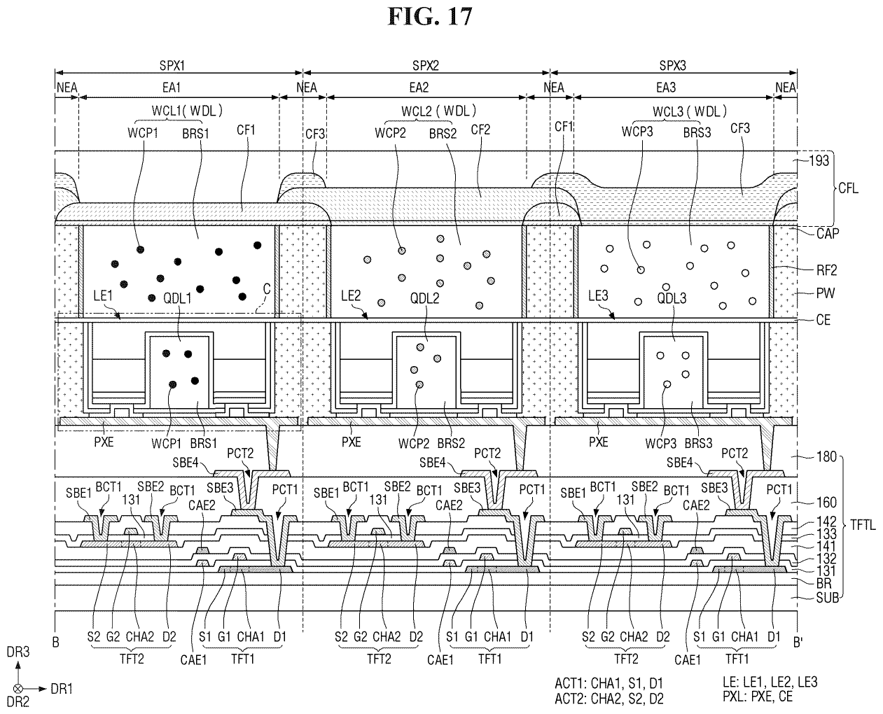

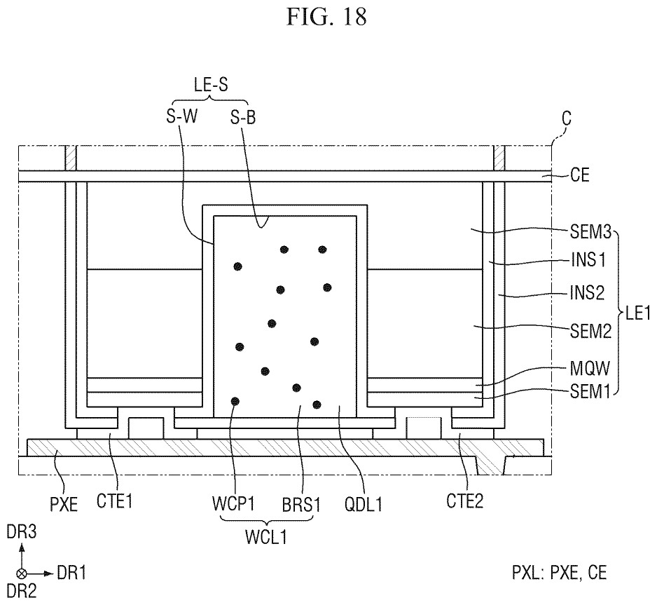

FIG. 17 is a cross-sectional view showing an example of a display panel taken along the line B-B′ of FIG. 6 according to still one or more other embodiments, and FIG. 18 is a cross-sectional view showing the configuration of the light-emitting element of FIG. 17. FIG. 18 is a detailed cross-sectional view showing an example of area C of FIG. 17.

Referring to FIG. 17, the display panel shown is different from the display panel described with reference to FIGS. 15 and 16 in that the light-emitting elements LE are vertical light-emitting elements, the light-emitting element LE is located on the pixel electrode PXE, and the common electrode CE is located on the light-emitting element LE. Redundant description of parts already described in the one or more embodiments corresponding to FIGS. 7 and 8 will be omitted.

The pixel electrode PXE may be located on the second organic layer 180. The pixel electrode PXE may be connected to the fourth source connection electrode SBE4 through a connection hole penetrating the second organic layer 180. The pixel electrode PXE may be connected to the first source region S1 or the first drain region D1 of the first thin film transistor TFT1 through the first source connection electrode SBE3 and the fourth source connection electrode SBE4. Accordingly, the voltage controlled by the first thin film transistor TFT1 may be applied to the pixel electrode PXE.

The pixel electrode PXE may be formed as a single layer or multiple layers made of any one of molybdenum (Mo), aluminum (Al), silver (Ag), platinum (Pt), palladium (Pd), chromium (Cr), gold (Au), titanium (Ti), nickel (Ni), neodymium (Nd), or copper (Cu) or an alloy thereof.

The contact electrodes CTE1 and CTE2 of the light-emitting element LE may directly contact the top of the pixel electrode PXE. The contact electrodes CTE1 and CTE2 may directly contact the first semiconductor layer SEM1. Accordingly, the contact electrodes CTE1 and CTE2 may electrically connect the pixel electrode PXE to the light-emitting element LE.

The contact electrode CTE of the light-emitting element LE may directly contact the top of the pixel electrode PXE. The contact electrode CTE may directly contact the first semiconductor layer SEM1. Accordingly, the contact electrode CTE may electrically connect the pixel electrode PXE to the light-emitting element LE.

The common electrode CE is located on the light-emitting element LE. The common electrode CE may include a transparent conductive material (TCO), such as indium tin oxide (ITO) and indium zinc oxide (IZO) capable of transmitting light.

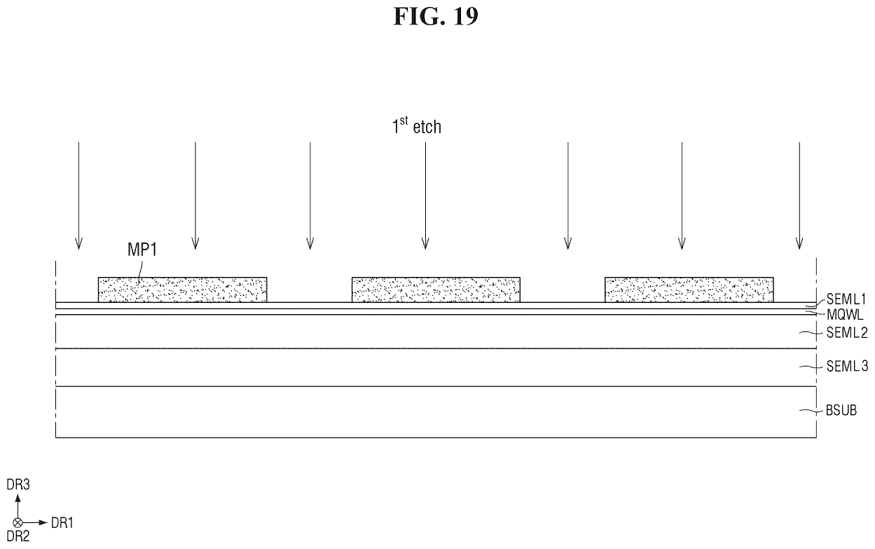

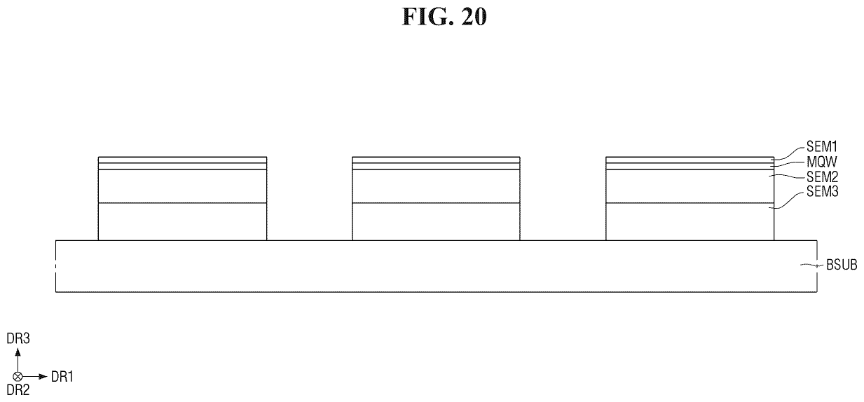

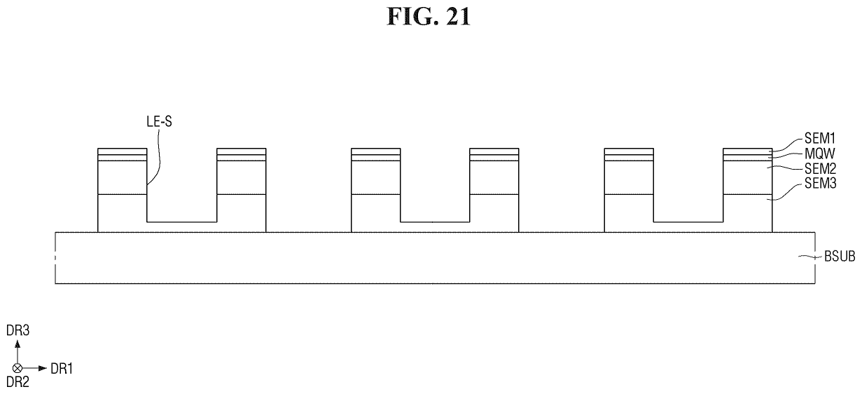

FIGS. 19 to 30 are cross-sectional views illustrating a method for manufacturing a display device according to one or more embodiments.

FIGS. 19 to 30 are cross-sectional views illustrating structures corresponding to the sequence of formation of the respective layers of the display device 10. FIGS. 19 to 30 mainly illustrate manufacturing processes of the light-emitting element LE, and these may generally correspond to the cross-sectional view of FIG. 7. Further, the drawings illustrate the one or more embodiments corresponding to FIGS. 5 to 8. Further, hereinafter, the first emission area EA1 of the display device 10 will be mainly described.

Referring to FIGS. 19 to 26, the plurality of light-emitting elements LE having the first wavelength conversion layer QDL1 are formed on a base substrate BSUB.

For example, the base substrate BSUB is prepared. The base substrate BSUB may be a sapphire substrate (Al₂O₃) or a silicon wafer containing silicon. However, the present disclosure is not limited thereto, and in one or more embodiments, a case in which the base substrate BSUB is a sapphire substrate will be described as an example.

A plurality of semiconductor material layers SEML3, SEML2, MQWL, and SEML1 are formed on a base substrate BSUB. In FIGS. 19 to 30, an electron-blocking layer and a superlattice layer are omitted. The plurality of semiconductor material layers grown by an epitaxial method may be formed by growing seed crystals. Here, the semiconductor material layer may be formed using one of electron beam deposition, physical vapor deposition (PVD), chemical vapor deposition (CVD), plasma laser deposition (PLD), dual-type thermal evaporation, sputtering, and metal organic chemical vapor deposition (MOCVD), preferably, using the metal organic chemical vapor deposition (MOCVD). However, the present disclosure is not limited thereto.

A precursor material for forming the plurality of semiconductor material layers may be selected to form a target material in a typically selectable range without any limitation. For example, the precursor material may be a metal precursor including an alkyl group, such as a methyl group or an ethyl group. Examples of the precursor material may include, but are not limited to, trimethylgallium Ga(CH₃)₃, trimethylaluminum Al(CH₃)₃, and triethyl phosphate (C₂H₅)₃PO₄.

For example, referring to FIG. 19, the undoped semiconductor material layer SEML3 is formed on the base substrate BSUB. The undoped semiconductor material layer SEML3 may be a semiconductor layer that is not doped with a dopant, that is, an undoped semiconductor layer. For example, the undoped semiconductor material layer SEML3 may be undoped-GaN that is not doped with a dopant.

Thereafter, the second semiconductor material layer SEML2, the active material layer MQWL, and the first semiconductor material layer SEML1 are sequentially formed on the undoped semiconductor material layer SEML3.

Next, referring to FIGS. 19 to 21, the plurality of semiconductor material layers SEML3, SEML2, MQWL, and SEML1 are etched using a mask MP1, and the plurality of semiconductor material layers SEML3, SEML2, MQWL, and SEML1 are partially etched to form the concave groove LE-S. In order to obtain the light-emitting element LE that does not include the concave groove LE-S, the process of partially etching the plurality of semiconductor material layers SEML3, SEML2, MQWL, and SEML1 is omitted.

The semiconductor material layers may be etched by a conventional method. For example, the process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, or the like. The dry etching method may be suitable for vertical etching because anisotropic etching can be performed. In the case of using the aforementioned etching technique, it may be possible to use Cl₂ or O₂ as an etchant. However, the present disclosure is not limited thereto.

Through these processes, a plurality of light-emitting elements LE may be obtained. Accordingly, the plurality of light-emitting elements LE are formed to include the undoped semiconductor layer SEM3, the second semiconductor layer SEM2, the active layer MQW, and the first semiconductor layer SEM1 having the concave groove LE-S.

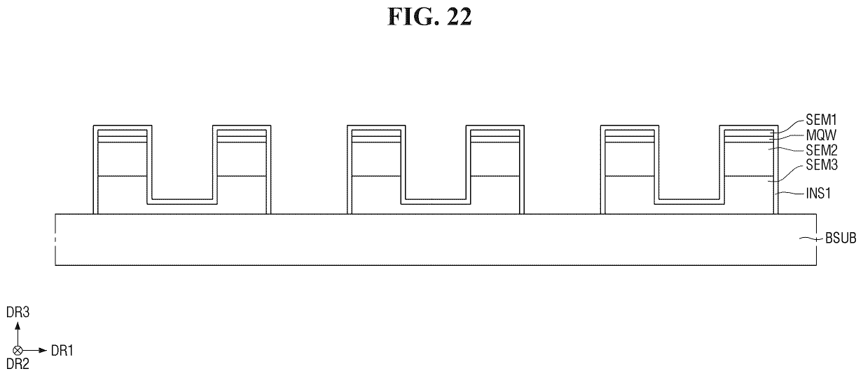

Referring to FIG. 22, the first protective layer INS1 is formed on the outer surfaces of the plurality of light-emitting elements LE having the concave grooves LE-S.

For example, the first protective layer INS1 is formed to cover the light-emitting element LE. Accordingly, the first protective layer INS1 may be formed not only on the outer surface of the light-emitting element LE, but also on the bottom and side surfaces of the concave groove LE-S.

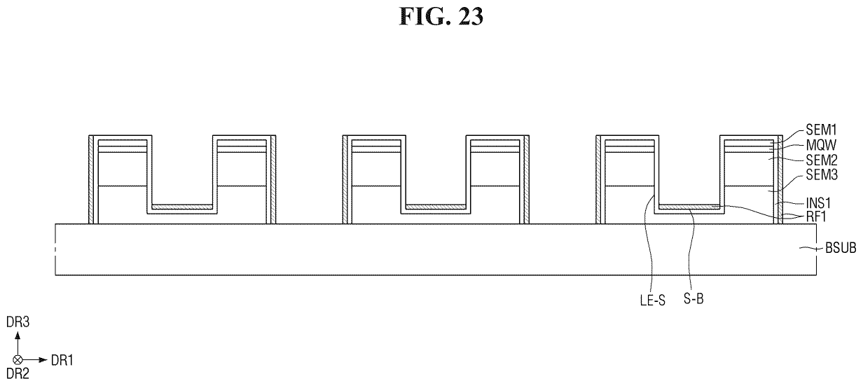

Next, referring to FIG. 23, the first reflective layer RF1 is formed on the bottom surface S-B of the concave groove LE-S and the outer surface of the light-emitting element LE.

For example, after forming a mask on the concave groove LE-S of the light-emitting element LE, a large voltage difference is generated in the third direction DR3, and the first reflective layer RF1 is etched by an etching material. In this case, the etching material may move in the third direction DR3 by voltage control, that is, move from the top to the bottom to etch the first reflective layer RF1. Thus, the first reflective layer RF1 located on the horizontal plane defined by the first direction DR1 and the second direction DR2 may be removed, while the first reflective layer RF1 located on the vertical plane defined by the third direction DR3 may not be removed. Thereafter, the first reflective layer RF1 may be formed on the bottom surface S-B of the concave groove LE-S using a mask.

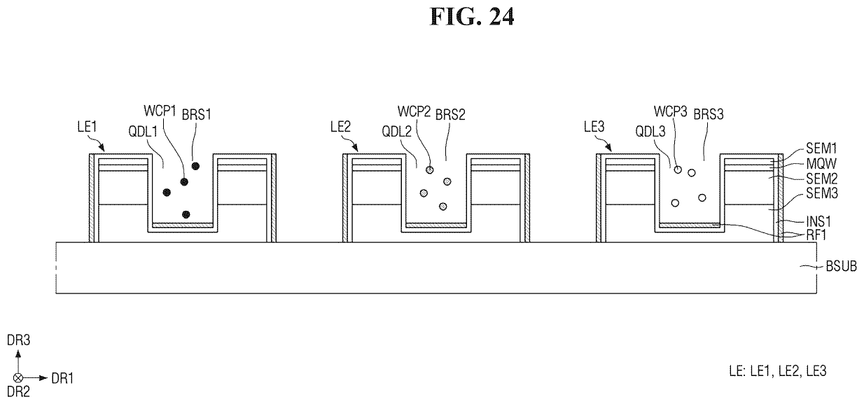

Next, referring to FIG. 24, the first wavelength conversion layer QDL1, QDL2 and QDL3 is formed in the concave groove LE-S. The first wavelength conversion layers QDL1, QDL2 and QDL3 may be formed in the plurality of concave grooves LE-S, respectively. The first wavelength conversion layer QDL1, QDL2 and QDL3 may be formed to fill the concave groove LE-S of the light-emitting element LE. For example, the concave groove LE-S of the first light-emitting element LE1 may be filled with a solution in which the first wavelength conversion particles WCP1 are mixed with the first base resin BRS1. The concave groove LE-S of the second light-emitting element LE2 may be filled with a solution in which the second wavelength conversion particles WCP2 are mixed with the second base resin BRS2. The concave groove LE-S of the third light-emitting element LE3 may be filled with a solution in which the third wavelength conversion particles WCP3 are mixed with the third base resin BRS3. The first wavelength conversion layer QDL1, QDL2 and QDL3 may be formed by a solution process such as, but not limited to, inkjet printing, imprinting, or the like using the mixed solution.

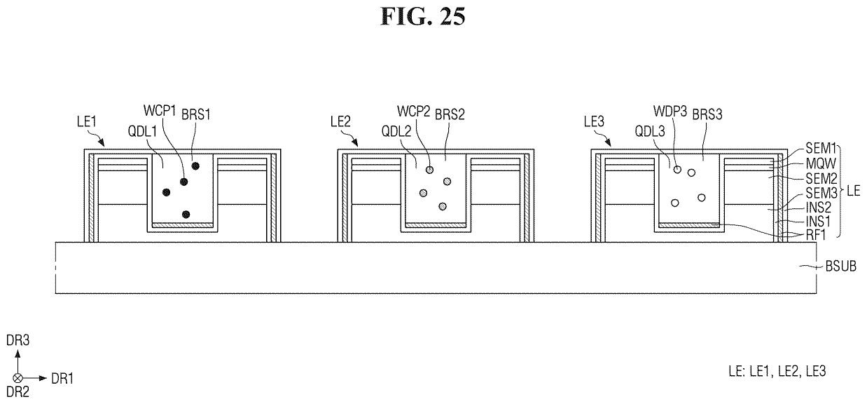

Next, as shown in FIG. 25, the second protective layer INS2 is formed to cover the outer surface of the light-emitting element LE. For example, the second protective layer INS2 is formed to cover the light-emitting element LE. Accordingly, it may be formed to cover not only the outer surface of the light-emitting element LE, but also the top surface of the first wavelength conversion layer QDL1, QDL2 and QDL3.

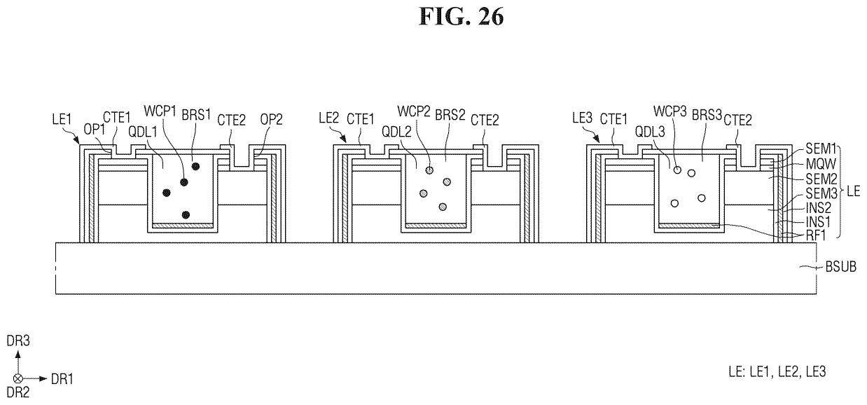

Next, as shown in FIG. 26, the first contact electrode CTE1 and the second contact electrode CTE2 are formed at the light-emitting element LE.

To this end, a first opening OP1 is formed to expose the top surface of the first semiconductor layer SEM1 from one surface of the light-emitting element LE. The first opening OP1 may be formed to penetrate the first protective layer INS1 and the second protective layer INS2 so that the first semiconductor layer SEM1 is exposed from one surface of the light-emitting element LE. Similarly, a second opening OP2 is formed to expose the top surface of the second semiconductor layer SEM2 from one surface of the light-emitting element LE. The second opening OP2 may be formed to penetrate the first protective layer INS1 and the second protective layer INS2 so that the second semiconductor layer SEM2 is exposed from one surface of the light-emitting element LE.

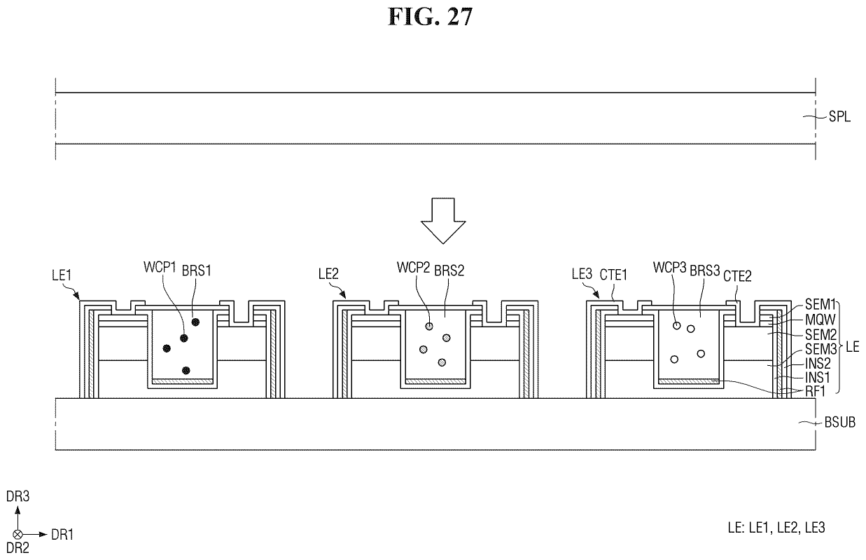

Next, referring to FIGS. 27 to 29, the light-emitting element LE may be transferred onto the pixel electrode layer PXL on the substrate SUB.

First, as shown in FIG. 27, a relay substrate SPL is aligned above the light-emitting elements LE. The relay substrate SPL may be configured with a support layer, and with a tackifying layer located on the support layer. The support layer may be made of a material that is transparent and that has mechanical stability to allow light to pass therethrough. The material of the support layer may include a transparent polymer, such as polyester, polyacrylic, polyepoxy, polyethylene, polystyrene, polyethylene terephthalate, or the like. The tackifying layer may contain a tackifying material for adhering the light-emitting element LE. For example, the tackifying material may include urethane acrylates, epoxy acrylates, polyester acrylates, or the like. The tackifying material may be a material whose tackiness changes as ultraviolet (UV) or heat is applied, and thus the tackifying layer may be easily separated from the light-emitting element LE.

The light-emitting elements LE are separated from the base substrate BSUB by irradiating the base substrate BSUB with a laser (1^{st} laser). The base substrate BSUB is separated from each of the undoped semiconductor layers SEM3 of the plurality of light-emitting elements LE.

The process of separating the base substrate BSUB may be a laser lift off (LLO) process. In the laser lift off process using laser, KrF excimer laser (e.g., about 248 nm wavelength) may be used as a source. The energy density of the excimer laser is irradiated in the range of about 550 mJ/cm² to about 950 mJ/cm², and the incident area may be in the range of about 50×50 μm² to about 1×1 cm², but the present disclosure is not limited thereto. By irradiating the laser to the base substrate BSUB, the base substrate BSUB may be separated from the light-emitting element LE.

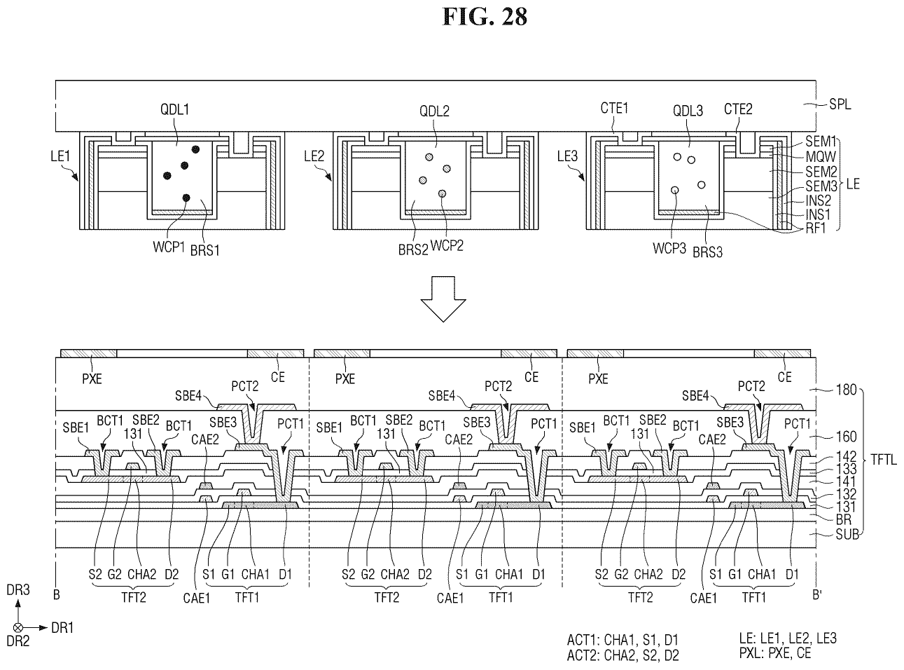

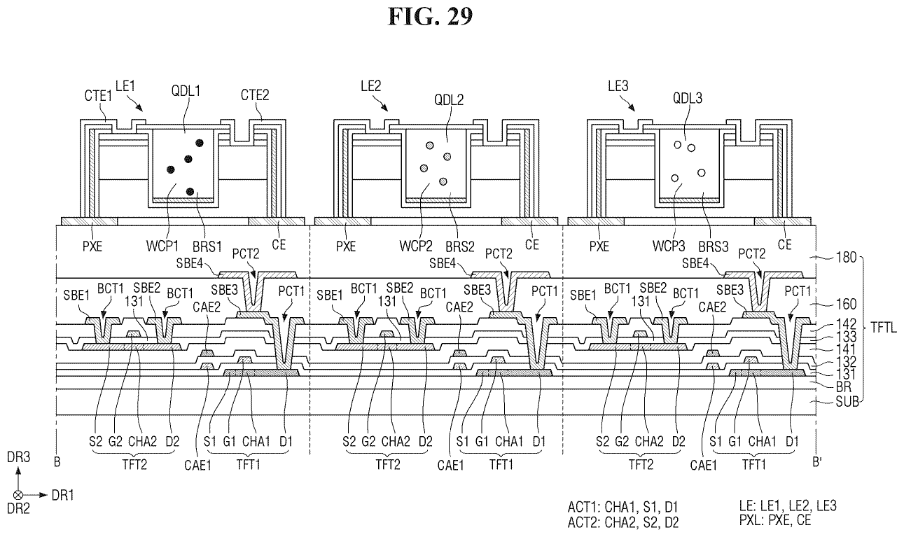

Thereafter, as shown in FIGS. 28 and 29, the light-emitting element LE may be selectively transferred onto the substrate SUB.

The substrate SUB, on which the pixel electrode PXE and the common electrode CE are located, is prepared, the plurality of light-emitting elements LE are located on the pixel electrode PXE and the common electrode CE, and one ends of the first contact electrode CTE1 and the second contact electrode CTE2 are respectively located on the pixel electrode PXE and the common electrode CE. In this case, the first contact electrode CTE1 may be connected to the pixel electrode PXE via a separate connection electrode, and the second contact electrode CTE2 may be connected to the common electrode CE via a separate connection electrode. The light-emitting element LE is bonded onto the pixel electrode PXE and the common electrode CE by applying heat and pressure or irradiating a laser to the connection electrode. Then, the relay substrate SPL is detached as shown in FIG. 29.

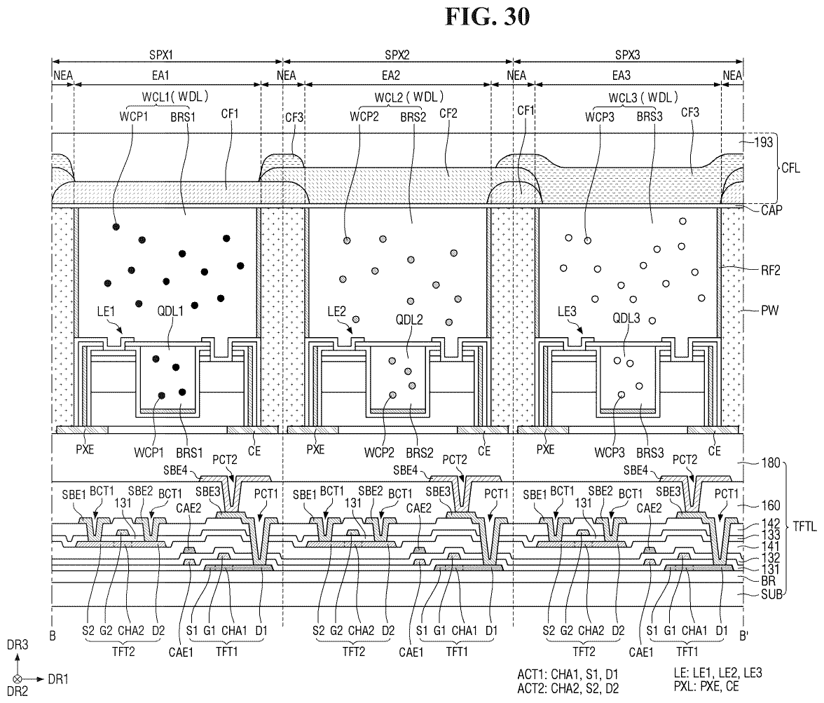

Referring to FIG. 30, the partition wall PW is formed between the plurality of light-emitting elements LE. The partition wall PW may be formed to be higher than the plurality of light-emitting elements LE. The second reflective layer RF2 is formed on the inner surface of the partition wall PW to be higher than the light-emitting element LE. Next, the second wavelength conversion layer WDL is formed in a space formed by the partition wall PW. In each emission area, the second wavelength conversion layer WDL may be formed of the same material as the overlapping first wavelength conversion layer QDL1, QDL2 or QDL3. For example, the second wavelength conversion layer WDL of the first emission area EA1 may be formed by filling a solution, in which the first wavelength conversion particles WCP1 are mixed with the first base resin BRS1, similarly to the first wavelength conversion layer QDL1. The second wavelength conversion layer WDL of the second emission area EA2 may be formed by filling a solution, in which the second wavelength conversion particles WCP2 are mixed with the second base resin BRS2, similarly to the first wavelength conversion layer QDL2. The second wavelength conversion layer WDL of the third emission area EA3 may be formed by filling a solution, in which the third wavelength conversion particles WCP3 are mixed with the third base resin BRS3, similarly to the first wavelength conversion layer QDL3.

Next, the capping layer CAP is formed on the partition wall PW, the second reflective layer RF2, and the second wavelength conversion layer WDL, and the color filters CF1, CF2, and CF3 are formed on the capping layer CAP. The first color filter CF1 may be formed by a photo process. The first color filter CF1 may have a thickness of about 1 μm or less, but is not limited thereto. Similarly, other color filters are also formed to respectively overlap the openings through a patterning process. Thereafter, the overcoat layer 193 is formed on the color filters CF1, CF2, and CF3.

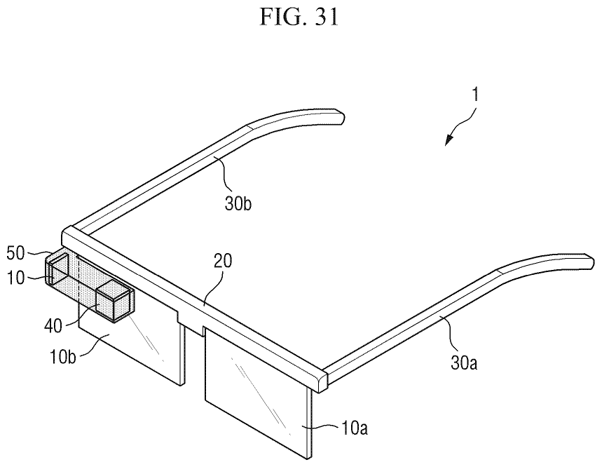

FIG. 31 is a diagram illustrating a virtual reality device including a display device according to one or more embodiments. FIG. 31 illustrates a virtual reality device 1 in which the display device 10 according to one or more embodiments is used.

Referring to FIG. 31, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 31 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 31, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 31 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

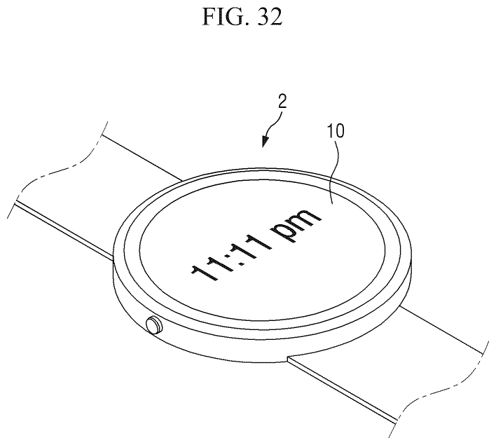

FIG. 32 is a diagram illustrating a smart device including a display device according to one or more embodiments.

Referring to FIG. 32, a display device 10 according to one or more embodiments may be applied to a smart watch 2 as one of smart devices.

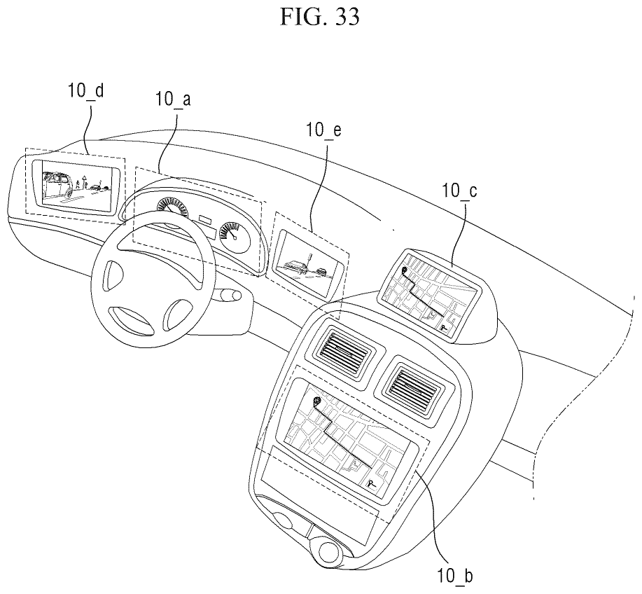

FIG. 33 is a diagram illustrating a vehicle including a display device according to one or more embodiments. FIG. 33 illustrates a vehicle in which display devices according to one or more embodiments are used.

Referring to FIG. 33, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

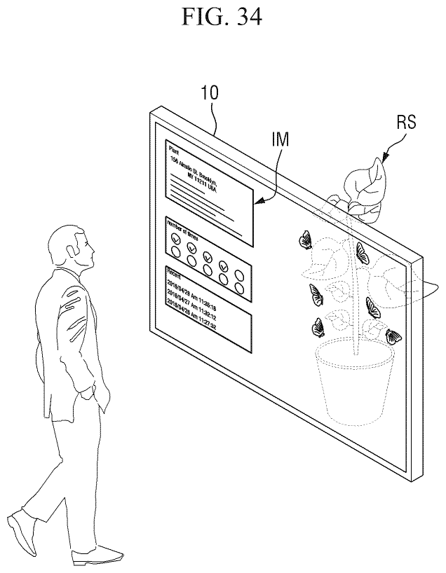

FIG. 34 is a diagram illustrating a transparent display device including a display device according to one or more embodiments.

Referring to FIG. 34, a display device 10 according to one or more embodiments may be applied to a transparent display device. The transparent display device may transmit light therethrough while displaying an image IM thereon. Therefore, a user located in front of the transparent display device may not only view the image IM displayed on the display device 10, but also may view an object RS or a background located in rear of the transparent display device. In case that the display device 10 is applied to the transparent display device, the substrate SUB of the display device 10 shown in FIG. 7 may include a light-transmitting portion that may transmit light therethrough or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

what is claimed is:

1. A light-emitting element comprising:
semiconductor layers comprising a first semiconductor layer, an active layer, a second semiconductor layer, and a third semiconductor layer, and defining at least one concave groove that is concave downwardly from one surface of the first semiconductor layer;
a first protective layer on side surfaces of the semiconductor layers, on a top surface of the first semiconductor layer, and on inner surfaces of the semiconductor layers and on the third semiconductor layer in the concave groove; and
a wavelength conversion layer containing wavelength conversion particles in the concave groove.

2. The light-emitting element of claim 1, wherein the concave groove penetrates the first semiconductor layer and the active layer, and is in at least a part of the second semiconductor layer or the third semiconductor layer.

3. The light-emitting element of claim 1, further comprising a groove reflective layer on the first protective layer in the concave groove.

4. The light-emitting element of claim 3, further comprising an external reflective layer surrounding side surfaces of the first semiconductor layer, the active layer, the second semiconductor layer, and the third semiconductor layer on the first protective layer.

5. The light-emitting element of claim 4, further comprising a second protective layer above the concave groove and covering the external reflective layer.

6. The light-emitting element of claim 1, wherein the concave groove has a cube shape, a cylindrical shape, or a shape with different respective widths at a top and a bottom thereof.

7. The light-emitting element of claim 1, wherein an area of the concave groove in plan view is about 50% or less of an area of the light-emitting element in plan view.

8. The light-emitting element of claim 1, further comprising:
a first contact electrode contacting the first semiconductor layer; and
a second contact electrode contacting the second semiconductor layer.

9. A display device comprising:
a substrate comprising a pixel electrode layer; and
light-emitting elements above the pixel electrode layer, and comprising:
semiconductor layers;
a first wavelength conversion layer in a concave groove that is concave in a downward direction from one surface of one of the semiconductor layers; and
a first protective layer on side surfaces of the semiconductor layers, on a top surface of a first light-emitting element of the light emitting elements, and on inner surfaces of the semiconductor layers and above one of the semiconductor layers in the concave groove.

10. The display device of claim 9, wherein the semiconductor layers comprise a first semiconductor layer, an active layer, a second semiconductor layer, and a third semiconductor layer, and
wherein the concave groove penetrates the first semiconductor layer and the active layer, and is in at least a part of the second semiconductor layer and the third semiconductor layer.

11. The display device of claim 9, wherein the light-emitting element further comprises a groove reflective layer on the first protective layer in the concave groove.

12. The display device of claim 11, wherein the semiconductor layers comprise a first semiconductor layer, an active layer, a second semiconductor layer, and a third semiconductor layer,
wherein the light-emitting element further comprises:
an external reflective layer surrounding side surfaces of the first semiconductor layer, the active layer, the second semiconductor layer, and the third semiconductor layer on the first protective layer; and
a second protective layer above the concave groove and covering the external reflective layer.

13. The display device of claim 9, wherein the concave groove has a cube shape, a cylindrical shape, or a shape with different widths at top and bottom.

14. The display device of claim 9, wherein the semiconductor layers comprise a first semiconductor layer, an active layer, a second semiconductor layer, and a third semiconductor layer, and
wherein an area of the concave groove in plan view is about 50% or less of an area of the light-emitting element in plan view.

15. The display device of claim 9, wherein the semiconductor layers comprise a first semiconductor layer, an active layer, a second semiconductor layer, and a third semiconductor layer,
wherein the first light-emitting element comprises a first contact electrode contacting the first semiconductor layer, and a second contact electrode contacting the second semiconductor layer, and
wherein the pixel electrode layer comprises a pixel electrode connected to the first contact electrode, and a common electrode spaced apart from the pixel electrode and connected to the second contact electrode.

16. The display device of claim 9, further comprising a common electrode on the first light-emitting element,
wherein the semiconductor layers comprise a first semiconductor layer, an active layer, a second semiconductor layer, and a third semiconductor layer,
wherein the pixel electrode layer comprises a pixel electrode, and
wherein the first light-emitting element further comprises a contact electrode connecting the first semiconductor layer to the pixel electrode.

17. The display device of claim 9, further comprising a second wavelength conversion layer above the light-emitting elements,
wherein the first wavelength conversion layer comprises a light transmission pattern or a wavelength conversion pattern, and
wherein the second wavelength conversion layer comprises another light transmission pattern or another wavelength conversion pattern overlapping the first wavelength conversion layer.

18. The display device of claim 9, wherein the light-emitting elements comprise the first light-emitting element configured to emit light of a first wavelength band, a second light-emitting element configured to emit light of a second wavelength band, and a third light-emitting element configured to emit light of a third wavelength band,
wherein the first wavelength conversion layer of the first light-emitting element is configured to convert light of a wavelength other than the first wavelength band into light of the first wavelength band,
wherein the first wavelength conversion layer of the second light-emitting element is configured to convert light of a wavelength other than the second wavelength band into light of the second wavelength band, and
wherein the first wavelength conversion layer of the third light-emitting element is configured to convert light of a wavelength other than the third wavelength band into light of the third wavelength band.

19. The display device of claim 9, further comprising a first color filter in a first emission area for transmitting only a first light of a first wavelength band, a second color filter in a second emission area for transmitting only light of a second wavelength band, and a third color filter in a third emission area for transmitting only light of a third wavelength band,
wherein the light-emitting elements are configured to emit the first light, and comprise the first light-emitting element in the first emission area, a second light-emitting element in the second emission area, and a third light-emitting element in the third emission area, and
wherein the first wavelength conversion layer of the light-emitting elements comprises a fourth wavelength conversion pattern containing fourth wavelength conversion particles configure to convert the first light into fourth light.

20. The display device of claim 9, wherein the light-emitting elements are configured to emit first light of a first wavelength band and comprise the first light-emitting element in a first emission area, a second light-emitting element in a second emission area, and a third light-emitting element in a third emission area,
wherein the first wavelength conversion layer of the second light-emitting element comprises a first wavelength conversion pattern containing first wavelength conversion particles for converting the first light into second light,
wherein the first wavelength conversion layer of the third light-emitting element comprises a second wavelength conversion pattern containing second wavelength conversion particles for converting the first light into third light, and
wherein the second wavelength conversion layer of the first emission area comprises a light transmission pattern containing a base resin and a scatterer for scattering light.

21. The display device of claim 9, further comprising a first color filter in a first emission area and transmitting only a first light of a first wavelength band, a second color filter in a second emission area and transmitting only second light of a second wavelength band, and a third color filter in a third emission area and transmitting only third light of a third wavelength band,
wherein the light-emitting elements comprise the first light-emitting element configured to emit the first light, a second light-emitting element configured to emit the second light, and a third light-emitting element configured to emit the third light, and
wherein the first wavelength conversion layer of the light-emitting elements comprises a fourth wavelength conversion pattern containing fourth wavelength conversion particles configured to convert the first light into fourth light.
